(19) United States
(12) Patent Application Publication
(10) Pub. No.: US 2024/0260329 A1
(43) Pub. Date: Aug. 1, 2024

(54) DISPLAY DEVICE AND DISPLAY PANEL

(71) Applicant: LG Display Co., Ltd., Seoul (KR)

(72) Inventors: SeokHyun KIM, Gyeonggi-do (KR); Seonha YU, Gyeonggi-do (KR); YuHo JUNG, Gyeonggi-do (KR); KwanSoo KIM, Gyeonggi-do (KR); JongWoo PARK, Gyeonggi-do (KR)

(73) Assignee: LG Display Co., Ltd., Seoul (KR)

(21) Appl. No.: 18/545,054

(22) Filed: Dec. 19, 2023

(30) Foreign Application Priority Data
Jan. 26, 2023 (KR) 10-2023-0009821

(51) Int. Cl. H10K 59/122; H10K 59/131; H10K 59/80

(52) U.S. Cl. CPC H10K 59/122; H10K 59/131; H10K 59/8052; H10K 2102/351

(57) ABSTRACT

A display device includes a substrate including a display area that allows one or more images to be displayed, and includes an optical area allowing light to be transmitted and a normal area located outside of the optical area; a first driving transistor on the substrate; a planarization layer disposed on the first driving transistor; a first anode electrode disposed in the optical area, located on the planarization layer, and electrically connected to the first driving transistor through a contact hole of the planarization layer; a bank located on the first anode electrode, and including a light emitting opening for exposing a portion of the first anode electrode; a first emission layer disposed in the optical area and contacting an upper surface of a portion of the first anode electrode exposed through the light emitting opening; a cathode electrode disposed in common in the optical area and the normal area, located on the first emission layer, and including a plurality of cathode holes in the optical area; and a plurality of metal patterning layers, each of which is disposed in a respective one of the plurality of cathode holes, and includes a non-metal material.

### CROSS-REFERENCE TO RELATED APPLICATION

This application claims the priority of Korean Patent Application No. 10-2023-0009821, filed on Jan. 26, 2023, which is hereby incorporated by reference in its entirety.

### BACKGROUND

### Field of the Disclosure

The present disclosure relates to electronic devices, and more particularly, to a display device and a display panel including one or more optical electronic devices not exposed on front surfaces thereof.

### Description of the Background

As display technology advances, display devices may provide increased functions, such as an image capture function, a sensing function, and the like, as well as an image display function. To provide these functions, a display device may need to include one or more optical electronic devices, such as a camera, a sensor for detecting an image, and the like.

To receive light transmitting through a front surface of a display device, it may be desirable for such an optical electronic device to be located in an area of the display device where incident light coming from the front surface may be increasingly received and detected. To achieve the foregoing, in a typical display device, an optical electronic device has been designed to be located in a front portion of the display device to allow a camera, a sensor, and/or the like as the optical electronic device to be increasingly exposed to incident light. To install an optical electronic device in a display device in this manner, a bezel area of the display device may be increased, or a notch or a hole may be needed to be formed in a display area of an associated display panel.

Therefore, as a display device needs an optical electronic device to receive or detect incident light, and perform an intended function, a size of the bezel in the front portion of the display device may be increased, or a substantial disadvantage may be encountered in designing the front portion of the display device.

In addition, in instances where an optical electronic device is configured in a display device, the quality of images may be unexpectedly decreased and the performance of the optical electronic device may be impaired according to structures in which the optical electronic device is configured in the display device. For example, in an instance where the optical electronic device is a camera, image quality acquired by the camera may be decreased.

The above information disclosed in this Background section is only for enhancement of understanding of the background of the described technology and therefore it may contain information that does not form prior art that is already known to a person of ordinary skill in the art.

### SUMMARY

Accordingly, the present disclosure is directed to a display device and a display panel that substantially obviate one or more of problems due to limitations and disadvantages described above.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

More specifically, the present disclosure is to provide a display panel and a display device that include a light transmission structure for enabling one or more optical electronic devices to normally receive light (e.g., visible light, infrared light, ultraviolet light, or the like) while not being exposed in a front surface of the display device.

One or more aspects of the present disclosure may provide a display panel and a display device that are capable of realizing a full screen display by using the entire area of the display panel as a display area by locating one or more optical electronic devices under the display area of the display panel such that the one or more optical electronic devices overlap with the display area of the display panel.

One or more aspects of the present disclosure may provide a display panel and a display device that are capable of enhancing reliability of light emitting elements by reducing decrease in luminance and decrease in lifetime in an optical area of the display panel overlapping with one or more optical electronic devices.

One or more aspects of the present disclosure may provide a display panel and a display device that include a bank structure suitable for an optical area of the display panel overlapping with one or more optical electronic devices.

One or more aspects of the present disclosure may provide a display panel and a display device that include a planarization layer structure suitable for an optical area of the display panel overlapping with one or more optical electronic devices.

One or more aspects of the present disclosure may provide a display panel and a display device that include a structure capable of improving transmittance of an optical area of the display panel overlapping with one or more optical electronic devices.

To achieve these and other advantages and in accordance with the present disclosure, as embodied and broadly described, a display device includes a substrate including a display area that allows one or more images to be displayed, and includes an optical area allowing light to be transmitted and a normal area located outside of the optical area; a first driving transistor on the substrate; a planarization layer disposed on the first driving transistor; a first anode electrode disposed in the optical area, located on the planarization layer, and electrically connected to the first driving transistor through a contact hole of the planarization layer; a bank located on the first anode electrode, and including a light emitting opening for exposing a portion of the first anode electrode; a first emission layer disposed in the optical area and contacting an upper surface of the portion of the first anode electrode exposed through the light emitting opening; a cathode electrode commonly disposed in the optical area and the normal area, located on the first emission layer, and including a plurality of cathode holes in the optical area; and a plurality of metal patterning layers, each of which is disposed in a respective one of the plurality of cathode holes, and includes a non-metal material.

In another aspect of the present disclosure, a display device includes a substrate comprising a display area in which one or more images may be displayed; an optical area configured to allow light to be transmitted through the substrate along a light transmission path; and a normal area located outside of the optical area. The display device further includes a first driving transistor on the substrate; a planarization layer disposed on the first driving transistor; and a first anode electrode, wherein the first anode electrode is: disposed in the optical area; located on the planarization layer; and electrically connected to the first driving transistor through a contact hole of the planarization layer. The display device further includes a bank located on the first anode electrode, the bank comprising a light emitting opening which exposes a portion of the first anode electrode; a first emission layer disposed in the optical area and contacting a surface of the portion of the first anode electrode exposed through the light emitting opening; and a cathode electrode commonly disposed in the optical area and the normal area, wherein the cathode electrode: is located on the first emission layer; and comprises a plurality of cathode holes in the optical area. The display device further includes a plurality of patterning layers, each of which is disposed in a respective one of the plurality of cathode holes, wherein each patterning layer comprises a non-metal material.

The bank may include a plurality of bank transmission openings located in a light transmission path in the optical area.

One metal patterning layer among the plurality of metal patterning layers may overlap with two bank transmission openings among the plurality of bank transmission openings, and the two bank transmission openings may be separated by a portion of the bank.

Each of the plurality of metal patterning layers may overlap with one bank transmission opening among the plurality of bank transmission openings.

The planarization layer may include a plurality of planarization layer transmission openings in the optical area.

The plurality of planarization layer transmission openings may be located in the light transmission path, and correspond to the plurality of bank transmission openings, respectively.

In a further as of the present disclosure, a display panel includes a substrate including a display area that allows one or more images to be displayed, and includes an optical area allowing light to be transmitted and a normal area located outside of the optical area; a first driving transistor on the substrate; a planarization layer disposed on the first driving transistor; a first anode electrode disposed in the optical area, located on the planarization layer, and electrically connected to the first driving transistor through a contact hole of the planarization layer; a bank located on the first anode electrode, and including a light emitting opening for exposing a portion of the first anode electrode; a first emission layer disposed in the optical area and contacting an upper surface of the portion of the first anode electrode exposed through the light emitting opening; a cathode electrode commonly disposed in the optical area and the normal area, located on the first emission layer, and including a plurality of cathode holes in the optical area.

In the display panel, at least one of the bank and the planarization layer may include at least one transmission opening in a light transmission path in the optical area.

According to one or more aspects of the present disclosure, a display panel and a display device may be provided that include a light transmission structure for enabling one or more optical electronic devices to normally receive light (e.g., visible light, infrared light, ultraviolet light, or the like) while not being exposed in a front surface of the display device.

One or more aspects of the present disclosure, a display panel and a display device may be provided that are capable of realizing a full screen display by using the entire area of the display panel as a display area by locating one or more optical electronic devices under the display area of the display panel such that the one or more optical electronic devices overlap with the display area of the display panel.

One or more aspects of the present disclosure, a display panel and a display device may be provided that include a bank structure suitable for an optical area of the display panel overlapping with one or more optical electronic devices.

One or more aspects of the present disclosure, a display panel and a display device may be provided that include a planarization layer structure suitable for an optical area of the display panel overlapping with one or more optical electronic devices.

One or more aspects of the present disclosure, a display panel and a display device may be provided that include a structure capable of improving transmittance of an optical area of the display panel overlapping with one or more optical electronic devices.

One or more aspects of the present disclosure, a display panel and a display device may be provided that are capable of enhancing reliability of light emitting elements by reducing decrease in luminance and decrease in lifetime of the light emitting elements caused by an ultraviolet process/inspection due to an etching structure (opening structure) of a bank and/or a planarization layer in an optical area of the display panel overlapping with one or more optical electronic devices.

Thus, by reducing decrease in luminance and decrease in lifespan of light emitting elements in the optical area, display panels and display devices having high efficiency and long lifespan (lifespan improvement) and enabling low power consumption design may be provided.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the appended claims. Nothing in this section should be taken as a limitation on those claims. It is to be understood that both the foregoing general description and the following detailed description of the present disclosure are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure.

In the drawings:

FIGS. 1A, 1B, and 1C illustrate an example display device according to aspects of the present disclosure;

FIG. 2 illustrates an example system configuration of the display device according to aspects of the present disclosure;

FIG. 3 illustrates an example display panel according to aspects of the present disclosure;

FIG. 4 schematically illustrates an example first type of optical area and an example normal area around the first type of optical area in the display panel according to aspects of the present disclosure;

FIGS. 5 and 6 illustrate example light emitting elements and example pixel circuits for driving the light emitting elements, which are disposed in a normal area, an optical bezel area, and an optical area in the display panel according to aspects of the present disclosure;

FIG. 7 is an example plan view of the normal area, the optical bezel area, and the optical area included in the display panel according to aspects of the present disclosure;

FIGS. 8 and 9 are example cross-sectional views of the display panel according to aspects of the present disclosure, and cross-sectional views of the optical bezel area and the optical area of the display panel;

FIG. 10 illustrates an example second type of optical area and an example normal area around the second type of optical area included in the display panel according to aspects of the present disclosure;

FIG. 11 is an example plan view of the second type of optical area in the display panel according to aspects of the present disclosure;

FIG. 12 is an example cross-sectional view of the second type of optical area in the display panel according to aspects of the present disclosure;

FIG. 13 illustrates an example cathode patterning process performed when manufacturing the display panel according to aspects of the present disclosure;

FIGS. 14 to 16 are example cross-sectional views of stackup configurations in an optical area of the display panel according to aspects of the present disclosure;

FIG. 17 illustrates example location relationships of a bank transmission opening and a metal patterning layer (or a cathode hole) in an optical area of the display panel according to aspects of the present disclosure;

FIG. 18A illustrates an example planar structure when one metal patterning layer overlap with two bank transmission openings in an optical area of the display panel according to aspects of the present disclosure;

FIG. 18B is a cross-sectional view taken along line A-A′ of FIG. 18A;

FIG. 19A illustrates an example planar structure when one metal patterning layer overlap with one bank transmission opening in an optical area of the display panel according to aspects of the present disclosure;

FIG. 19B is a cross-sectional view taken along line B-B′ of FIG. 19A;

FIG. 20 illustrates example planar structures according to open ratios of a bank in an optical area of the display panel according to aspects of the present disclosure;

FIG. 21A illustrates an example planar structure of a first combination of a metal patterning layer, a bank transmission opening, and a planarization layer transmission opening in an optical area of the display panel according to aspects of the present disclosure;

FIG. 21B is a cross-sectional view taken along line C-C′ of FIG. 21A;

FIG. 22A illustrates an example planar structure of a second combination of the metal patterning layer, the bank transmission opening, and the planarization layer transmission opening in the optical area of the display panel according to aspects of the present disclosure;

FIG. 22B is a cross-sectional view taken along line D-D′ of FIG. 22A;

FIG. 23A illustrates an example planar structure of a third combination of the metal patterning layer, the bank transmission opening, and the planarization layer transmission opening in the optical area of the display panel according to aspects of the present disclosure; and

FIG. 23B is a cross-sectional view taken along line E-E′ of FIG. 23A.

### DETAILED DESCRIPTION

Reference will now be made in detail to aspects of the present disclosure, examples of which may be illustrated in the accompanying drawings.

In the following description, the structures, aspects, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example aspects described with reference to the accompanying drawings. The present disclosure may, however, be embodied in different forms and should not be construed as limited to the example aspects set forth herein. Rather, these example aspects are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example aspects of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts or overlap with” etc. a second element, it should be interpreted that, not only may the first element “be directly connected or coupled to” or “directly contact or overlap with” the second element, but a third element may also be “interposed” between the first and second elements, or the first and second elements may “be connected or coupled to”, “contact or overlap with”, etc. each other via a fourth element. Here, the second element may be included in at least one of two or more elements that “are connected or coupled to”, “contact or overlap with”, etc. each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an element or feature, or corresponding information (e. g., level, range, etc.) include a tolerance or error range that may be caused by various factors (e. g., process factors, internal or external impact, noise, etc.) even when a relevant description is not specified. Further, the term “may” fully encompasses all the meanings of the term “may”.

Hereinafter, various aspects of the present disclosure will be described in detail with reference to the accompanying drawings. In addition, for convenience of description, a scale in which each of the elements is illustrated in the accompanying drawings may differ from an actual scale. Thus, the illustrated elements are not limited to the specific scale in which they are illustrated in the drawings.

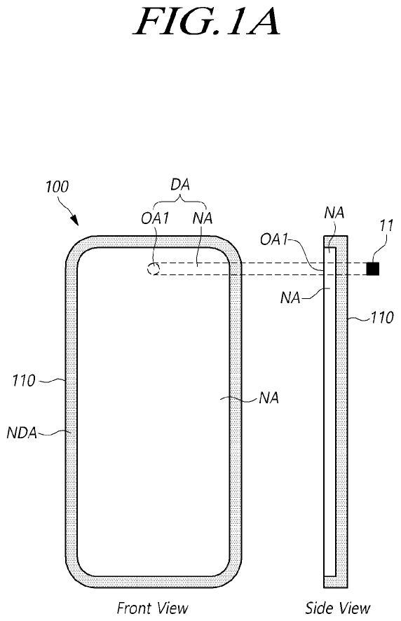

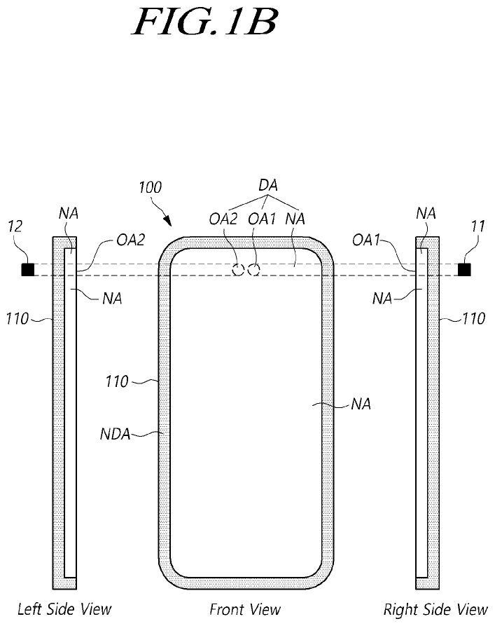

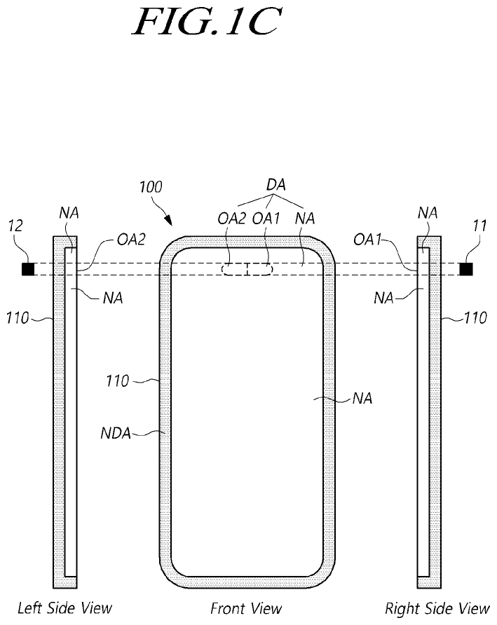

FIGS. 1A, 1B, and 1C illustrate an example display device 100 according to aspects of the present disclosure.

Referring to FIGS. 1A, 1B, and 1C, in one or more aspects, the display device 100 according to aspects of the present disclosure may include a display panel 110 for displaying one or more images, and one or more optical electronic devices (11 and/or 12). Herein, an optical electronic device may be referred to as a light detector, a light receiver, or a light sensing device. An optical electronic device may include one or more of a camera, a camera lens, a sensor, a sensor for detecting images, or the like.

The display panel 110 may include a display area DA in which one or more images may be displayed and a non-display area NDA in which an image is not displayed.

A plurality of subpixels may be arranged in the display area DA, and several types of signal lines for driving the plurality of subpixels may be arranged therein.

The non-display area NDA may refer to an area outside of the display area DA. Several types of signal lines may be arranged in the non-display area NDA, and several types of driving circuits may be connected thereto. At least a portion of the non-display area NDA may be bent to be invisible (i.e. not be visible) from the front surface of the display device 100 or may be covered by a case or housing (not shown) of the display device 100. The non-display area NDA may be also referred to as a bezel or a bezel area.

Referring to FIGS. 1A, 1B, and 1C, in one or more aspects, in the display device 100 according to aspects of the present disclosure, one or more optical electronic devices (11 and/or 12) may be prepared independently of, and installed in, the display panel 110, and be located under, or in a lower portion of, the display panel 110 (an opposite side of a viewing or external surface thereof).

Light may enter the front surface (the viewing surface) of the display panel 110, pass through the display panel 110, reach one or more optical electronic devices (11 and/or 12) located under, or in the lower portion of, the display panel 110 (the opposite side of the viewing surface). Light transmitting through the display panel 110 may include, for example, visible light, infrared light, or ultraviolet light.

The one or more optical electronic devices (11 and/or 12) may be devices capable of receiving or detecting light transmitting through the display panel 110 and perform a predefined function based on the received light. For example, the one or more optical electronic devices (11 and/or 12) may include one or more of the following: an image capture device such as a camera (an image sensor), and/or the like; or a sensor such as a proximity sensor, an illuminance sensor, and/or the like. Such a sensor may be, for example, an infrared sensor capable of detecting infrared light.

Referring to FIGS. 1A, 1B, and 1C, in one or more aspects, the display area DA of the display panel 110 according to aspects of the present disclosure may include one or more optical areas (OA1 and/or OA2) and a normal area NA. The one or more optical areas allow light to be transmitted through the display panel e.g. through a substrate of the display panel. The normal area may be opaque or substantially opaque and/or may be less transmissive than the optical area. Herein, the term “normal area” NA is an area that while being present in the display area DA, does not overlap with one or more optical electronic devices (11 and/or 12) and may also be referred to as a non-optical area. The one or more optical areas (OA1 and/or OA2) may be one or more areas respectively overlapping with the one or more optical electronic devices (11 and/or 12) in a cross-sectional view of the display panel 110.

According to an example of FIG. 1A, the display area DA may include a first optical area OA1 and a normal area NA. In this example, at least a portion of the first optical area OA1 may overlap with a first optical electronic device 11.

According to an example of FIG. 1B, the display area DA may include a first optical area OA1, a second optical area OA2, and a normal area NA. In this example, a portion of the normal area NA may be present between the first optical area OA1 and the second optical area OA2. At least a portion of the first optical area OA1 may overlap with the first optical electronic device 11, and at least a portion of the second optical area OA2 may overlap with a second optical electronic device 12.

According to an example of FIG. 1C, the display area DA may include a first optical area OA1, a second optical area OA2, and a normal area NA. In this example, the normal area NA may not be present between the first optical area OA1 and the second optical area OA2. For example, the first optical area OA1 and the second optical area OA2 may contact each other (e.g., directly contact each other). In this example, at least a portion of the first optical area OA1 may overlap with the first optical electronic device 11, and at least a portion of the second optical area OA2 may overlap with the second optical electronic device 12.

In the display panel 110 or the display device 100 according to aspects of the present disclosure, it may be desirable that both an image display structure and a light transmission structure are implemented in the one or more optical areas (OA1 and/or OA2). For example, since the one or more optical areas (OA1 and/or OA2) are portions of the display area DA, it may be therefore desirable that light emitting areas of subpixels for displaying one or more images are disposed in the one or more optical areas (OA1 and/or OA2). Further, to enable light to be transmitted through the one or more optical electronic devices (11 and/or 12), it may be desirable that a light transmission structure is implemented in the one or more optical areas (OA1 and/or OA2).

It should be noted that even though the one or more optical electronic devices (11 and/or 12) are devices that need to receive light, the one or more optical electronic devices (11 and/or 12) may be located on the back of the display panel 110 (e. g., on an opposite side of the viewing surface thereof), and thereby, may receive light that has passed through the display panel 110. For example, the one or more optical electronic devices (11 and/or 12) may not be exposed in the front surface (viewing surface) of the display panel 110 or the display device 100. Accordingly, when a user faces the front surface of the display device 110, the one or more optical electronic devices (11 and/or 12) are located so that they cannot be visible to the user.

The first optical electronic device 11 may be, for example, a camera, and the second optical electronic device 12 may be, for example, a sensor. The sensor may be a proximity sensor, an illuminance sensor, an infrared sensor, and/or the like. In one or more aspects, the camera may be a camera lens, an image sensor, or a unit including at least one of the camera lens and the image sensor, and the sensor may be an infrared sensor capable of detecting infrared light. In another aspect, the first optical electronic device 11 may be a sensor, and the second optical electronic device 12 may be a camera.

Hereinafter, for convenience of descriptions related to the optical electronic devices (11 and 12), the first optical electronic device 11 is considered to be a camera, and the second optical electronic device 12 is considered to be an infrared sensor. It should be, however, understood that the scope of the present disclosure includes examples where the first optical electronic device 11 is an infrared sensor, and the second optical electronic device 12 is a camera. The camera may be, for example, a camera lens, an image sensor, or a unit including at least one of the camera lens and the image sensor.

In an example where the first optical electronic device 11 is a camera, this camera may be located on the back of (e. g., under, or in a lower portion of) the display panel 110, and be a front camera capable of capturing objects or images in a front direction of the display panel 110. Accordingly, the user may capture an image or object through the camera that is invisible on the viewing surface while looking at the viewing surface of the display panel 110.

Although the normal area NA and the one or more optical areas (OA1 and/or OA2) included in the display area DA in each of FIGS. 1A, 1B, and 1C are areas where images are allowed to be displayed, the normal area NA is an area where a light transmission structure need not be implemented, but the one or more optical areas (OA1 and/or OA2) are areas where a light transmission structure need be implemented. Thus, in one or more aspects, the normal area NA is an area where a light transmission structure is not implemented or included, and the one or more optical areas (OA1 and/or OA2) are areas in which a light transmission structure is implemented or included.

Accordingly, the one or more optical areas (OA1 and/or OA2) may have a transmittance greater than or equal to a predetermined level, e. g., a relatively high transmittance, and the normal area NA may have a transmittance less than the predetermined level or not have light transmittance.

For example, the one or more optical areas (OA1 and/or OA2) may have a resolution, a subpixel arrangement structure, a number of subpixels per unit area, an electrode structure, a line structure, an electrode arrangement structure, a line arrangement structure, and/or the like different from that/those of the normal area NA.

In one aspect, the number of subpixels per unit area in the one or more optical areas (OA1 and/or OA2) may be less than the number of subpixels per unit area in the normal area NA. For example, the resolution of the one or more optical areas (OA1 and/or OA2) may be lower than that of the normal area NA. In this example, the number of subpixels per unit area may have the same meaning as a resolution, a pixel density, or a degree of integration of pixels. For example, the unit of the number of subpixels per unit area may be pixels per inch (PPI), which represents the number of pixels within 1 inch.

In the examples of FIGS. 1A, 1B, and 1C, the number of subpixels per unit area in the first optical areas OA1 may be less than the number of subpixels per unit area in the normal area NA. In the examples of FIGS. 1B and 1C, the number of subpixels per unit area in the second optical areas OA2 may be greater than or equal to the number of subpixels per unit area in the first optical areas OA1, and be less than the number of subpixels per unit area in the normal area NA.

In one or more aspects, as a method for increasing respective transmittance of at least one of the first optical area OA1 and the second optical area OA2, a pixel density differentiation design scheme as described above may be applied in which a difference in densities of pixels (or subpixels) or in degrees of integration of pixels (or subpixels) between the first optical area OA1, the second optical area OA2, and the normal area NA may be produced. According to the pixel density differentiation design scheme, in an aspect, the display panel 110 may be configured or designed such that the number of subpixels per unit area of at least one of the first optical area OA1 and the second optical area OA2 is less than the number of subpixels per unit area of the normal area NA.

In one or more aspects, as another method for increasing respective transmittance of at least one of the first optical area OA1 and the second optical area OA2, a pixel size differentiation design scheme may be applied in which a difference in sizes of pixels (or subpixels) between the first optical area OA1, the second optical area OA2, and the normal area NA may be produced. According to the pixel size differentiation design scheme, the display panel PNL may be configured or designed such that while the number of subpixels per unit area of at least one of the first optical area OA1 and the second optical area OA2 is equal to or similar to the number of subpixels per unit area of the normal area NA, a size of each subpixel (i. e., a size of a corresponding light emitting area) disposed in at least one of the first optical area OA1 and the second optical area OA2 is smaller than a size of each subpixel (i. e., a size of a corresponding light emitting area) disposed in the normal area NA.

In one or more aspects, for convenience of description, discussions that follow are provided based on the pixel density differentiation design scheme of the two schemes (i.e., the pixel density differentiation design scheme and the pixel size differentiation design scheme) for increasing respective transmittance of at least one of the first optical area OA1 and the second optical area OA2, unless explicitly stated otherwise. It should be therefore understood that in descriptions that follow, a small number of subpixels per unit area may be considered as corresponding to a small size of subpixel, and a large number of subpixels per unit area may be considered as corresponding to a large size of subpixel.

In the examples of FIGS. 1A, 1B, and 1C, the first optical area OA1 may have various shapes, such as a circle, an ellipse, a quadrangle, a hexagon, an octagon or the like. In the examples of FIGS. 1B and 1C, the second optical area OA2 may have various shapes, such as a circle, an ellipse, a quadrangle, a hexagon, an octagon or the like. The first optical area OA1 and the second optical area OA2 may have the same or substantially or nearly the same shape, or different shapes.

Referring to FIG. 1C, in the example where the first optical area OA1 and the second optical area OA2 contact each other (e.g., directly contact each other), the entire optical area including the first optical area OA1 and the second optical area OA2 may also have various shapes, such as a circle, an ellipse, a quadrangle, a hexagon, an octagon or the like. Hereinafter, for convenience of descriptions related to shapes of the optical areas (OA1 and OA2), each of the first optical area OA1 and the second optical area OA2 is considered to have a circular shape. It should be, however, understood that the scope of the present disclosure includes examples where at least one of the first optical area OA1 and the second optical area OA2 have a shape other than a circular shape.

According to one or more aspects of the present disclosure, when the display device 100 has a structure in which the first optical electronic device 11 such as a camera, and the like is located under, or in a lower portion of, the display panel 100 without being exposed to the outside, such a display device may be referred to as a display in which under-display camera (UDC) technology is implemented.

The display device 100 in which such under-display camera (UDC) technology is implemented may provide an advantage of preventing a reduction of an area or size of the display area DA because a notch or a camera hole for exposing a camera need not be formed in the display panel 110. Indeed, since a notch or a camera hole for camera exposure need not be formed in the display panel 110, the display device 100 may provide further advantages of reducing the size of a bezel area, and improving the degree of freedom in design because such limitations to the design are removed.

Although the one or more optical electronic devices (11 and/or 12) are located on the back of (e.g., under, or in a lower portion of) the display panel 110 of the display device 100 (e.g., hidden or not exposed to the outside), it is desirable that the one or more optical electronic devices (11 and/or 12) are able to perform their normal predefined functionalities by receiving or detecting light.

Further, although one or more optical electronic devices (11 and/or 12) are located on the back of (e. g., under, or in a lower portion of) the display panel 110 to be hidden and thus located to overlap with the display area DA, it is desirable that the display device 100 is able to normally display one or more images in the one or more optical areas (OA1 and/or OA2) overlapping with the one or more optical electronic devices (11 and/or 12) in the display area DA. Thus, even though one or more optical electronic devices (11 and/or 12) are located on the back of the display panel, the display device 100 according to aspects of the present disclosure may be configured to display images in a normal manner (e. g., without reduction in image quality) in the one or more optical areas (OA1 and/or OA2) overlapping with the one or more optical electronic devices (11 and/or 12) in the display area DA.

Since the foregoing first optical area OA1 is configured or designed as a transmittable area, the quality of image display in the first optical area OA1 may be different from the quality of image display in the normal area NA.

Further, when designing the first optical area OA1 for the purpose of improving the quality of image display, there may be caused a situation that the transmittance of the first optical area OA1 is reduced.

To address these issues, in one or more aspects, the first optical area OA1 included in the display device 100 or the display panel may be configured with, or include, a structure capable of preventing a difference (e.g., non-uniformity) in image quality between the first optical area OA1 and the normal area NA from being caused, and improving the transmittance of the first optical area OA1.

Further, not only the first optical area OA1, but the second optical area OA2 included in the display device 100 or the display panel 110 according to aspects of the present disclosure may be configured with, or include, a structure capable of improving the image quality of the second optical area OA2, and improving the transmittance of the second optical area OA2.

It should be also noted that the first optical area OA1 and the second optical area OA2 included in the display device 100 or the display panel 110 according to aspects of the present disclosure may be differently implemented or have different utilization examples while having a similarity in terms of light transmittable areas. Taking account of such a distinction, the structure of the first optical area OA1 and the structure of the second optical area OA2 in the display device 100 according to aspects of the present disclosure may be configured or designed differently from each other.

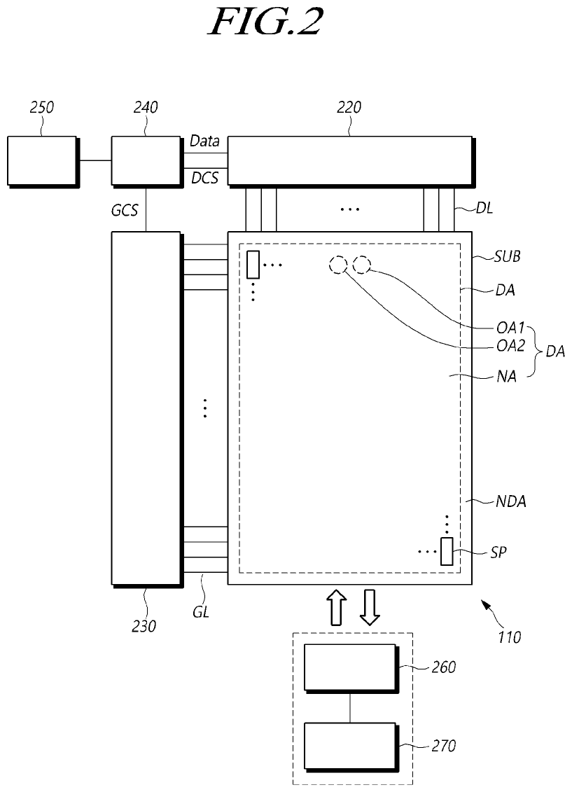

FIG. 2 illustrates an example system configuration of the display device 100 according to one or more aspects of the present disclosure.

Referring to FIG. 2, the display device 100 may include the display panel 110 and a display driving circuit as components for displaying one or more images.

The display driving circuit may be a circuit for driving the display panel 110, and include a data driving circuit 220, a gate driving circuit 230, a display controller 240, and other circuit components.

The display panel 110 may include a display area DA in which one or more images may be displayed and a non-display area NDA in which an image is not displayed. The non-display area NDA may be an area outside of the display area DA, and may also be referred to as an edge area or a bezel area. All or a portion of the non-display area NDA may be an area visible from the front surface of the display device 100, or an area that is bent and invisible from the front surface of the display device 100.

The display panel 110 may include a substrate SUB and a plurality of subpixels SP disposed on the substrate SUB. The display panel 110 may further include various types of signal lines to drive the plurality of subpixels SP.

In one or more aspects, the display device 100 according to aspects of the present disclosure may be a liquid crystal display device, or the like, or a self-emission display device in which light is emitted from the display panel 110 itself. In examples where the display device 100 according to aspects of the present disclosure is implemented as a self-emission display device, each of the plurality of subpixels SP may include a light emitting element. For example, the display device 100 according to aspects of the present disclosure may be an organic light emitting display device implemented with one or more organic light emitting diodes (OLED). In another example, the display device 100 according to aspects of the present disclosure may be an inorganic light emitting display device implemented with one or more inorganic material-based light emitting diodes. In further another example, the display device 100 according to aspects of the present disclosure may be a quantum dot display device implemented with quantum dots, which are self-emission semiconductor crystals.

The structure of each of the plurality of subpixels SP may be differently configured or designed according to types of the display devices 100. For example, in an example where the display device 100 is a self-emission display device including self-emission subpixels SP, each subpixel SP may include a self-emission light emitting element, one or more transistors, and one or more capacitors.

In one or more aspects, various types of signal lines arranged in the display device 100 may include, for example, a plurality of data lines DL for carrying data signals (which may be referred to as data voltages or image signals), a plurality of gate lines GL for carrying gate signals (which may be referred to as scan signals), and the like.

The plurality of data lines DL and the plurality of gate lines GL may intersect each other. Each of the plurality of data lines DL may extend in a first direction. Each of the plurality of gate lines GL may extend in a second direction different from the first direction. For example, the first direction may be a column or vertical direction, and the second direction may be a row or horizontal direction. In another example, the first direction may be the row or horizontal direction, and the second direction may be the column or vertical direction.

The data driving circuit 220 may be a circuit for driving the plurality of data lines DL, and may supply data signals to the plurality of data lines DL. The gate driving circuit 230 may be a circuit for driving the plurality of gate lines GL, and may supply gate signals to the plurality of gate lines GL.

The display controller 240 may be a device for controlling the data driving circuit 220 and the gate driving circuit 230, and may control driving times for the plurality of data lines DL and driving times for the plurality of gate lines GL.

The display controller 240 may supply a data driving control signal DCS to the data driving circuit 220 to control the data driving circuit 220, and supply a gate driving control signal GCS to the gate driving circuit 230 to control the gate driving circuit 230.

The display controller 240 may receive input image data from a host system 250 and supply image data Data to the data driving circuit 220 based on the input image data.

The data driving circuit 220 may receive digital image data Data from the display controller 240, convert the received image data Data into analog data signals, and supply the resulting analog data signals to the plurality of data lines DL.

The gate driving circuit 230 may receive a first gate voltage corresponding to a turn-on level voltage and a second gate voltage corresponding to a turn-off level voltage along with various gate driving control signals GCS, generate gate signals, and supply the generated gate signals to the plurality of gate lines GL.

In one or more aspects, the data driving circuit 220 may be connected to the display panel 110 in a tape automated bonding (TAB) type, or connected to a conductive pad such as a bonding pad of the display panel 110 in a chip on glass (COG) type or a chip on panel (COP) type, or connected to the display panel 110 in a chip on film (COF) type.

In one or more aspects, the gate driving circuit 230 may be connected to the display panel 110 in the tape automated bonding (TAB) type, or connected to a conductive pad such as a bonding pad of the display panel 110 in the chip on glass (COG) type or the chip on panel (COP) type, or connected to the display panel 110 in the chip on film (COF) type. In another aspect, the gate driving circuit 230 may be disposed in the non-display area NDA of the display panel 110 in a gate in panel (GIP) type. The gate driving circuit 230 may be disposed on the substrate, or connected to the substrate. That is, in the case of the GIP type, the gate driving circuit 230 may be disposed in the non-display area NDA of the substrate. In the case of the chip on glass (COG) type, the chip on film (COF) type, or the like, the gate driving circuit 230 may be connected to the substrate.

In one or more aspects, at least one of the data driving circuit 220 and the gate driving circuit 230 may be disposed in the display area DA of the display panel 110. For example, at least one of the data driving circuit 220 and the gate driving circuit 230 may be disposed such that it does not overlap with subpixels SP, or disposed such that it overlap with one or more, or all, of the subpixels SP, or at least respective one or more portions of one or more subpixels.

The data driving circuit 220 may be located in, and/or electrically connected to, but not limited to, only one side or portion (e.g., an upper edge or a lower edge) of the display panel 110. In one or more aspects, the data driving circuit 220 may be located in, and/or electrically connected to, but not limited to, two sides or portions (e.g., an upper edge and a lower edge) of the display panel 110 or at least two of four sides or portions (e.g., the upper edge, the lower edge, a left edge, and a right edge) of the display panel 110 according to driving schemes, panel design schemes, or the like.

The gate driving circuit 230 may be located in, and/or electrically connected to, but not limited to, only one side or portion (e.g., a left edge or a right edge) of the display panel 110. In one or more aspects, the gate driving circuit 230 may be located in, and/or electrically connected to, but not limited to, two sides or portions (e.g., a left edge and a right edge) of the panel 110 or at least two of four sides or portions (e.g., an upper edge, a lower edge, the left edge, and the right edge) of the panel 110 according to driving schemes, panel design schemes, or the like.

The display controller 240 may be implemented in a separate component from the data driving circuit 220, or incorporated in the data driving circuit 220 and thus implemented in an integrated circuit.

The display controller 240 may be a timing controller used in the typical display technology or a controller or a control device capable of performing other control functions in addition to the function of the typical timing controller. In one or more aspects, the display controller 140 may be a controller or a control device different from the timing controller, or a circuitry or a component included in the controller or the control device. The display controller 240 may be implemented with various circuits or electronic components such as an integrated circuit (IC), a field programmable gate array (FPGA), an application specific integrated circuit (ASIC), a processor, and/or the like.

The display controller 240 may be mounted on a printed circuit board, a flexible printed circuit, and/or the like and be electrically connected to the gate driving circuit 220 and the data driving circuit 230 through the printed circuit board, flexible printed circuit, and/or the like.

The display controller 240 may transmit signals to, and receive signals from, the data driving circuit 220 via one or more predefined interfaces. For example, such interfaces may include a low voltage differential signaling (LVDS) interface, an embedded clock point-point interface (EPI), a serial peripheral interface (SPI), and the like.

In one or more aspects, to further provide a touch sensing function, as well as an image display function, the display device 100 according to aspects of the present disclosure may include at least one touch sensor, and a touch sensing circuit capable of detecting whether a touch event occurs by a touch object such as a finger, a pen, or the like, or of detecting a corresponding touch position (or touch coordinates), by sensing the touch sensor.

The touch sensing circuit may include: a touch driving circuit 260 capable of generating and providing touch sensing data by driving and sensing the touch sensor; a touch controller 270 capable of detecting the occurrence of a touch event or detecting a touch position (or touch coordinates) using the touch sensing data; and one or more other components.

The touch sensor may include a plurality of touch electrodes. The touch sensor may further include a plurality of touch lines for electrically connecting the plurality of touch electrodes to the touch driving circuit 260.

The touch sensor may be implemented in the form of a touch panel outside of the display panel 110 or be integrated inside of the display panel 110. In the example where the touch sensor is implemented in the form of the touch panel outside of the display panel 110, such a touch sensor may be referred to as an add-on type. In the example where the add-on type of touch sensor is disposed in the display device 100, the touch panel and the display panel 110 may be separately manufactured and combined in an assembly process. The add-on type of touch panel may include a touch panel substrate and a plurality of touch electrodes on the touch panel substrate.

In the example where the touch sensor is integrated inside of the display panel 110, the touch sensor may be formed on the substrate SUB together with signal lines and electrodes related to display driving during a process of manufacturing the display panel 110.

The touch driving circuit 260 may supply a touch driving signal to at least one of a plurality of touch electrodes, and sense at least one of the plurality of touch electrodes to generate touch sensing data.

The touch sensing circuit may perform touch sensing using a self-capacitance sensing technique or a mutual-capacitance sensing technique.

In the example where the touch sensing circuit performs touch sensing using the self-capacitance sensing technique, the touch sensing circuit may perform touch sensing based on capacitance between each touch electrode and a touch object (e. g., a finger, a pen, and the like). According to the self-capacitance sensing technique, each of the plurality of touch electrodes may serve as both a driving touch electrode and a sensing touch electrode. The touch driving circuit 260 may drive all, or one or more, of the plurality of touch electrodes and sense all, or one or more, of the plurality of touch electrodes.

In the example where the touch sensing circuit performs touch sensing using the mutual-capacitance sensing technique, the touch sensing circuit may perform touch sensing based on capacitance between touch electrodes. According to the mutual-capacitance sensing technique, the plurality of touch electrodes are divided into driving touch electrodes and sensing touch electrodes. The touch driving circuit 260 may drive the driving touch electrodes and sense the sensing touch electrodes.

The touch driving circuit 260 and the touch controller 270 included in the touch sensing circuit may be implemented in separate devices or in a single device. Further, the touch driving circuit 260 and the data driving circuit 220 may be implemented in separate devices or in a single device.

The display device 100 may further include a power supply circuit for supplying various types of power to the display driving circuit and/or the touch sensing circuit.

The display device 100 according to aspects of the present disclosure may represent, but not be limited to, a mobile terminal such as a smart phone, a tablet, or the like, a monitor, a television (TV), or the like. Aspects of the present disclosure are not limited thereto. In one or more aspects, the display device 100 may be display devices, or include displays, of various types, sizes, and shapes for displaying information or images.

As described above, the display area DA of the display panel 110 may include the normal area NA and the one or more optical areas (OA1 and/or OA2) as illustrated in FIGS. 1A, 1B, and 1C. The normal area NA and the one or more optical areas (OA1 and/or OA2) may be areas where images may be displayed. It should be noted here that the normal area NA may be an area in which a light transmission structure need not be implemented, and the one or more optical areas (OA1 and/or OA2) may be areas in which a light transmission structure is implemented.

As discussed above with respect to the examples of FIGS. 1A, 1B, and 1C, even though the display area DA of the display panel 110 may include the one or more optical areas (OA1 and/or OA2) together with the normal area NA, for convenience of description, discussions that follow will be provided based on examples where the display area DA includes both the first and second optical areas OA1 and OA2 (i.e., the first optical area OA1 of FIGS. 1A, 1B, and 1C, and the second optical area OA2 of FIGS. 1B and 1C) and the normal area NA (i.e., the normal area NA of FIGS. 1A, 1B, and 1C).

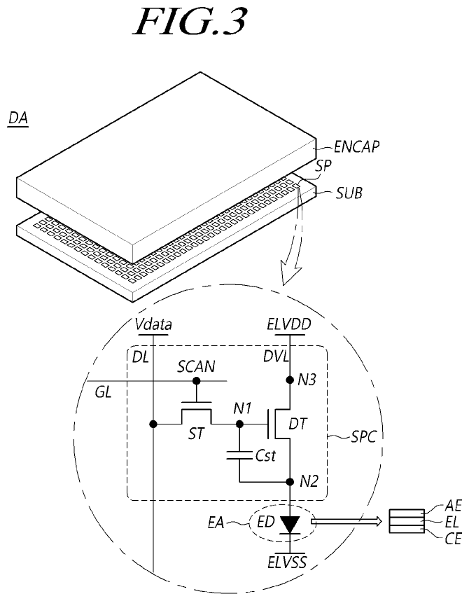

FIG. 3 illustrates an example system configuration of the display device 110 according to aspects of the present disclosure.

Referring to FIG. 3, a plurality of subpixels SP may be disposed in the display area DA of the display panel 110. The plurality of subpixels SP may be disposed in a normal area (e.g., the normal area of FIGS. 1A, 1B, and 1C), a first optical area (e.g., the first optical area OA1 of FIGS. 1A, 1B, and 1C), and a second optical area (e.g., the second optical area OA2 of FIGS. 1B and 1C) included in the display area DA of the display panel 110.

Referring to FIG. 3, each of the plurality of subpixels SP may include a light emitting element ED and a pixel circuit SPC configured to drive the light emitting element ED.

Referring to FIG. 3, the pixel circuit SPC may include a driving transistor DT for driving the light emitting element ED, a scan transistor ST for transferring a data voltage Vdata to a first node N1 of the driving transistor DT, a storage capacitor Cst for maintaining a voltage at an approximately constant level during one frame, and the like.

The driving transistor DT may include the first node N1 to which a data voltage is applied, a second node N2 electrically connected to the light emitting element ED, and a third node N3 to which a driving voltage ELVDD through a driving voltage line DVL is applied. In the driving transistor DT, the first node N1 may be a gate node, the second node N2 may be a source node or a drain node, and the third node N3 may be the drain node or the source node. For convenience of description, descriptions that follow will be provided based on examples where the first, second and third nodes (N1, N2 and N3) of the driving transistor DT are gate, source and drain nodes, respectively, unless explicitly stated otherwise. However, it should be understood that the scope of the present disclosure includes examples where the first, second and third nodes (N1, N2 and N3) of the driving transistor DT are gate, drain and source nodes, respectively.

The light emitting element ED may include an anode electrode AE, an emission layer EL, and a cathode electrode CE. The anode electrode AE may represent a pixel electrode disposed in each subpixel SP, and may be electrically connected to the second node N2 of the driving transistor DT of each subpixel SP. The cathode electrode CE may represent a common electrode being disposed in the plurality of subpixels SP in common, and a base voltage ELVSS such as a low-level voltage, a ground voltage, or the like may be applied to the cathode electrode CE.

For example, the anode electrode AE may be a pixel electrode, and the cathode electrode CE may be a common electrode. In another example, the anode electrode AE may be a common electrode, and the cathode electrode CE may be a pixel electrode. For convenience of description, discussions that follow will be provided based on examples where the anode electrode AE is a pixel electrode, and the cathode electrode CE is a common electrode unless explicitly stated otherwise. However, it should be understood that the scope of the present disclosure includes examples where the anode electrode AE is a common electrode, and the cathode electrode CE is a pixel electrode.

The light emitting element ED may include a light emitting area EA having a predetermined size or area. The light emitting area EA of the light emitting element ED may be defined as, for example, an area in which the anode electrode AE, the emission layer EL, and the cathode electrode CE overlap with one another.

The light emitting element ED may be, for example, an organic light emitting diode (OLED), an inorganic light emitting diode, a quantum dot light emitting element, or the like. In the example where an organic light emitting diode (OLED) is used as the light emitting element ED, the emission layer EL thereof may include an organic emission layer including an organic material.

The scan transistor ST may be turned on and off by a scan signal SCAN, which is a gate signal applied through a gate line GL, and be electrically connected between the first node N1 of the driving transistor DT and a data line DL.

The storage capacitor Cst may be electrically connected between the first node N1 and the second node N2 of the driving transistor DT.

The pixel circuit SPC may be configured with two transistors (2T: DRT and SCT) and one capacitor (1C: Cst) (which may be referred to as a “2TIC structure”) as shown in FIG. 3, and in one or more implementations, may further include one or more transistors, and/or further include one or more capacitors.

In one or more aspects, the storage capacitor Cst, which may be present between the first node N1 and the second node N2 of the driving transistor DT, may be an external capacitor intentionally configured or designed to be located outside of the driving transistor DT, other than internal capacitors, such as parasitic capacitors (e.g., a gate-to-source capacitance Cgs, a gate-to-drain capacitance Cgd, and the like). Each of the driving transistor DT and the scan transistor ST may be an n-type transistor or a p-type transistor.

Since circuit elements (in particular, a light emitting element ED implemented with an organic light emitting diode including an organic material) included in each subpixel SP are vulnerable to external moisture or oxygen, an encapsulation layer ENCAP may be disposed in the display panel 110 to prevent external moisture or oxygen from penetrating into such circuit elements. The encapsulation layer ENCAP may be disposed such that it covers the light emitting element ED.

Hereinafter, for convenience of description, the term “optical area OA” is used instead of distinctly describing the first optical area OA1 and the second optical area OA2 described above. Thus, it should be noted that an optical area described below may represent any one or both of the first and second optical area OA1 and OA2 described above, unless explicitly stated otherwise.

Likewise, for convenience of description, the term “optical electronic device” is used instead of distinctly describing the first optical electronic device 11 and the second optical electronic device 12 described above. Thus, it should be noted that an optical electronic device described below may represent any one or both of the first and second optical electronic device 11 and 12 described above, unless explicitly stated otherwise.

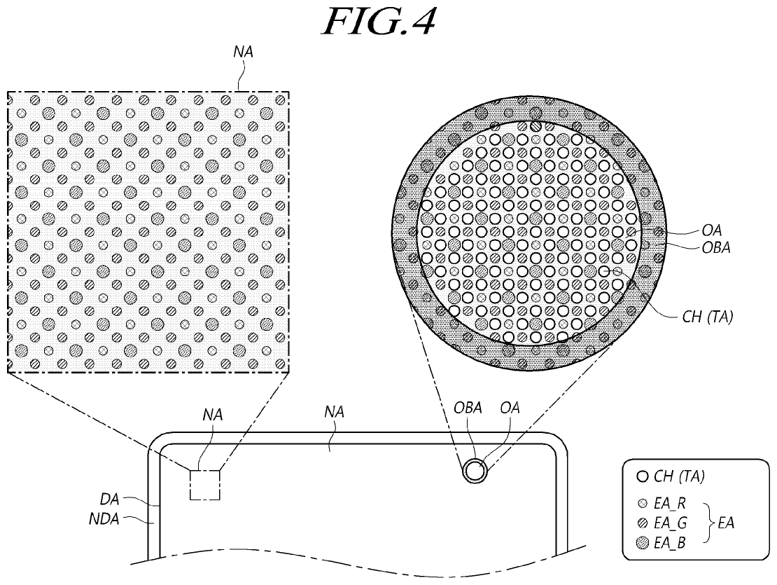

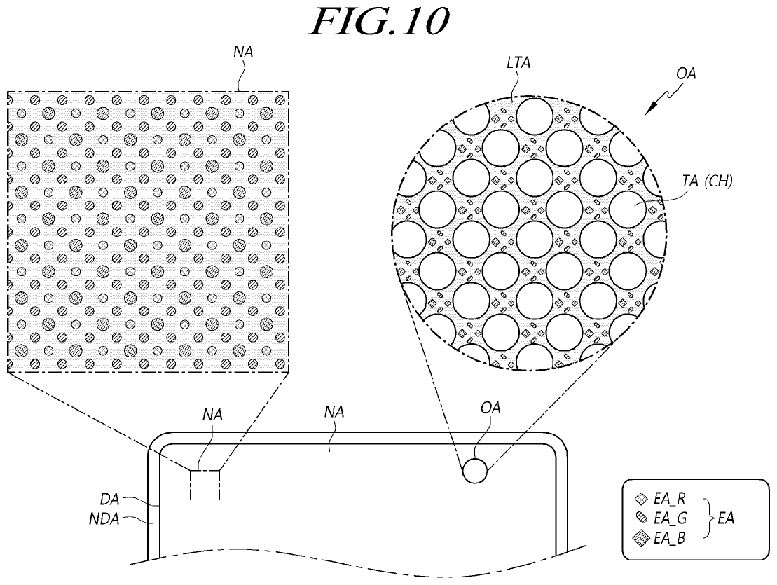

Hereinafter, an example first type of optical area OA will be described with reference to FIGS. 4 to 9, and an example second type of optical area OA will be described with reference to FIGS. 10 to 12.

The first type of optical area OA and the second type of optical area OA are briefly described as follows.

In the case of the first type of optical area OA, one or more pixel circuits SPC for driving one or more light emitting elements ED disposed in the optical area OA may be disposed in an area outside of the optical area OA without being in the optical area OA.

In the case of the second type pf optical area OA, one or more pixel circuits SPC for driving one or more light emitting elements ED disposed in the optical area OA may be disposed the optical area OA.

FIG. 4 schematically illustrates an example first type of optical area OA and an example normal area NA around the first type of optical area OA in the display panel 110 according to aspects of the present disclosure.

Referring to FIG. 4, in one or more aspects, the display panel 110 according to aspects of the present disclosure may include a display area (e. g., the display area DA of figures described above) where one or more images may be displayed and a non-display area (e. g., the non-display area NDA of figures described above) where an image is not displayed.

Referring to FIG. 4, the display area DA may include an optical area OA through which light may be transmitted, and a normal area NA around the optical area OA.

The optical area OA may have the structure of a first type. Thus, in an example where the optical area OA is implemented in the first type, an optical bezel area OBA may be disposed outside of the optical area OA. In one or more aspects, the optical bezel area OBA may represent a part of the normal area NA.

In other words, when the optical area OA is implemented in the first type, the display area DA may include the optical area OA, the normal area NA located outside of the optical area OA, and the optical bezel area OBA between the optical area OA and the normal area NA.

Referring to FIG. 4, the optical area OA may be an area overlapping with an optical electronic device and be a transmittable area through which light used for operation of the optical electronic device may be transmitted.

The light transmitting through the optical area OA may include light of a single wavelength band or light of various wavelength bands. For example, the optical area OA may be configured to allow, but not limited to, at least one of visible light, infrared light, ultraviolet light, and the like to be transmitted.

An optical electronic device disposed in the optical area OA may receive light transmitting through the optical area OA and perform a predefined operation using the received light. The light received by the optical electronic device through the optical area OA may include at least one of visible light, infrared light, and ultraviolet light.

For example, in an example where the optical electronic device is a camera, the light used for the predefined operation of the optical electronic device, which has passed through the optical area OA, may include visible light.

In another example, in an example where the optical electronic device is an infrared sensor, the light used for the predefined operation of the optical electronic device, which has passed through the optical area OA, may include infrared (also referred to as infrared light).

Referring to FIG. 4, the optical bezel area OBA may represent an area located outside of the optical area OA. The normal area NA may represent an area located outside of the optical bezel area OBA. The optical bezel area OBA may be disposed between the optical area OA and the normal area NA.

For example, the optical bezel area OBA may be disposed outside of only a portion of an edge of the optical area OA, or disposed outside of the entire edge of the optical area OA.

In the example where the optical bezel area OBA is disposed outside of the entire edge of the optical area OA, the optical bezel area OBA may have a ring shape surrounding the optical area OA.

For example, the optical area OA may have various shapes such as a circular shape, an elliptical shape, a polygonal shape, an irregular shape, or the like. The optical bezel area OBA may have various ring shapes (e.g., a circular ring shape, an elliptical ring shape, a polygonal ring shape, an irregular ring shape, or the like) surrounding the optical area OA having various shapes.

Referring to FIG. 4, the display area DA may include a plurality of light emitting areas EA. Since the optical area OA, the optical bezel area OBA, and the normal area NA are areas included in the display area DA, each of the optical area OA, the optical bezel area OBA, and the normal area NA may include a plurality of light emitting areas EA.

For example, the plurality of light emitting areas EA may include a first color light emitting area emitting light of a first color, a second color light emitting area emitting light of a second color, and a third color light emitting area emitting light of a third color.

At least one of the first color light emitting area, the second color light emitting area, and the third color light emitting area may have a different area or size from the remaining one or more light emitting areas.

The first color, the second color, and the third color may be different colors from one another, and may be various colors. For example, the first color, second color, and third color may be or include red, green, and blue, respectively.

Hereinafter, for convenience of description, the first color, the second color, and the third color are considered to be red, green, and blue, respectively. However, aspects of the present disclosure are not limited thereto.

In the example where the first color, the second color, and the third color are red, green, and blue, respectively, an area of a blue light emitting area EA_B may be greater than an area of a red light emitting area EA_R and an area of a green light emitting area EA_G.

A light emitting element ED disposed in the red light emitting area EA_R may include an emission layer EL emitting red light. A light emitting element ED disposed in the green light emitting area EA_G may include an emission layer EL emitting green light. A light emitting element ED disposed in the blue light emitting area EA_B may include an emission layer EL emitting blue light.

In terms of material, an organic material included in the emission layer EL emitting blue light may be more easily degraded than respective organic materials included in the emission layer EL emitting red light and the emission layer EL emitting green light.

In one or more aspects, as the blue light emitting area EA_B is configured or designed to have the largest area or size, current density supplied to the light emitting element ED disposed in the blue light emitting area EA_B may be the least. Therefore, a degradation degree of a light emitting element ED disposed in the blue light emitting area EA_B may be similar to a degradation degree of a light emitting element ED disposed in the red light emitting area EA R and a degradation degree of a light emitting element ED disposed in the green light emitting area EA_G.

In consequence, a difference in degradation between the light emitting element ED disposed in the red light emitting area EA_R, the light emitting elements ED disposed in the green light emitting area EA_G, and the light emitting elements ED disposed in the blue light emitting area EA_B cannot be produced or may be reduced, and therefore, the display device 100 or the display panel 110 according to aspects of the present disclosure may provide an advantage of improving image quality. In addition, as a difference in degradation between the light emitting element ED disposed in the red light emitting area EA_R, the light emitting elements ED disposed in the green light emitting area EA_G, and the light emitting elements ED disposed in the blue light emitting area EA_B is eliminated or reduced, the display device 100 or the display panel 110 according to aspects of the present disclosure may therefore provide an advantage of reducing a difference in lifespan between the light emitting element ED disposed in the red light emitting area EA_R, the light emitting elements ED disposed in the green light emitting area EA_G, and the light emitting elements ED disposed in the blue light emitting area EA B.

Referring to FIG. 4, it is desirable that the optical area OA, which is a transmittable area, has high transmittance. To meet this requirement, a cathode electrode (e.g., the cathode electrode CE of FIG. 3) may include a plurality of cathode holes CH in the optical area OA. That is, in the optical area OA, the cathode electrode CE may include a plurality of cathode holes CH.

Referring to FIG. 4, in one or more aspects, the cathode electrode CE may not include a cathode hole CH in the normal area NA. That is, in the normal area NA, the cathode electrode CE may not include a cathode hole CH.

In one or more aspects, the cathode electrode CE may not include a cathode hole CH in the optical bezel area OBA. That is, in the optical bezel area OBA, the cathode electrode CE may not include a cathode hole CH.

In the optical area OA, the plurality of cathode holes CH formed in the cathode electrode CE may be referred to as a plurality of transmission areas TA or a plurality of opening areas. Although FIG. 4 illustrates that each cathode hole CH has a respective circular shape, one or more cathode holes CH may have various shapes other than the circular shape, such as an elliptical shape, a polygonal shape, an irregular shape or the like.

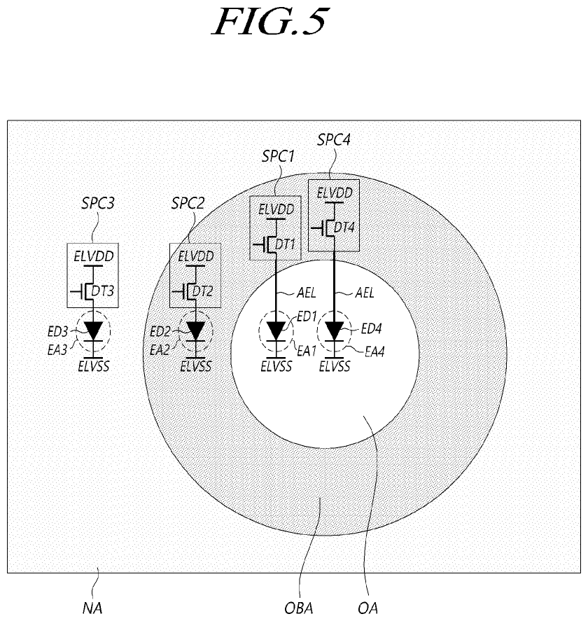

FIG. 5 illustrates an example configuration of the display panel 110 according to aspects of the present disclosure. As illustrated in FIG. 5, the display panel 110 may include light emitting elements (ED1, ED2, ED3, and ED4) disposed in the normal area NA, the optical bezel area OBA, and the optical area OA, and pixel circuits (SPC1, SPC2, SPC3, and SPC4) for driving the light emitting elements (ED1, ED2, ED3, and ED4).

It should be understood here that each of the pixel circuits (SPC1, SPC2, SPC3, and SPC4) may include transistors (DT and ST), a storage capacitor Cst, and the like as shown in FIG. 3. However, it should be noted that for convenience of explanation, each of the pixel circuits (SPC1, SPC2, SPC3, and SPC4) is simply expressed as only a respective driving transistor (DT1, DT2, DT3, and DT4).

Referring to FIG. 5, the normal area NA, the optical area OA, and the optical bezel area OBA may have structural differences as well as positional differences.

As one example of such structural differences, one or more pixel circuits (SPC1, SPC2, SPC3, and/or SPC4) may be disposed in the optical bezel area OBA and the normal area NA, but a pixel circuit may not be disposed in the optical area OA. For example, the optical bezel area OBA and the normal area NA may be configured to allow one or more transistors (DT1, DT2, DT3, and/or DT4) to be disposed therein, but the optical area OA may be configured not to allow a transistor to be disposed therein.

Transistors and storage capacitors included in the pixel circuits (SPC1, SPC2, SPC3, and SPC4) may be components causing transmittance to be reduced. Thus, since a pixel circuit (e. g., SPC1, SPC2, SPC3, or SPC4) is not disposed in the optical area OA, the transmittance of the optical area OA may be more improved.

In one or more aspects, although the pixel circuits (SPC1, SPC2, SPC3, and SPC4) may be disposed only in the normal area NA and the optical bezel area OBA, the light emitting elements (ED1, ED2, ED3, and ED4) may be disposed in the normal area NA, the optical bezel area OBA, and the optical area OA.

Referring to FIG. 5, although a first light emitting element ED1 may be disposed in the optical area OA, a first pixel circuit SPC1 for driving the first light emitting element ED1 may not be located in the optical area OA.

Referring to FIG. 5, the first pixel circuit SPC1 for driving the first light emitting element ED1 disposed in the optical area OA may be disposed in the optical bezel area OBA, not in the optical area OA.

Hereinafter, the normal area NA, the optical area OA, and the optical bezel area OBA will be described in more detail.

Referring to FIG. 5, in one or more aspects, the plurality of light emitting areas EA included in the display panel 110 according to aspects of the present disclosure may include a first light emitting area EA1, a second light emitting area EA2, and a third light emitting area EA3. In these aspects, the first light emitting area EA1, the second light emitting area EA2, and the third light emitting area EA3 may be included in the optical area OA, the optical bezel area OBA, and the normal area NA, respectively. Hereinafter, it is assumed that the first light emitting area EA1, the second light emitting area EA2, and the third light emitting area EA3 are areas emitting light of a same color.

Referring to FIG. 5, in one or more aspects, the display panel 110 according to aspects of the present disclosure may include: a first light emitting element ED1 disposed in the optical area OA1 and having the first light emitting area EA1; a second light emitting element ED2 disposed in the optical bezel area OBA1 and having the second light emitting area EA2; and a third light emitting element ED3 disposed in the normal area NA and having the third light emitting area EA3.

Referring to FIG. 5, in one or more aspects, the display panel 110 according to aspects of the present disclosure may further include a first pixel circuit SPC1 configured to drive the first light emitting element ED1, a second pixel circuit SPC2 configured to drive the second light emitting element ED2, and a third pixel circuit SPC3 configured to drive the third light emitting element ED3.

Referring to FIG. 5, the first pixel circuit SPC1 may include a first driving transistor DT1. The second pixel circuit SPC2 may include a second driving transistor DT2. The third pixel circuit SPC3 may include a third driving transistor DT3.

Referring to FIG. 5, in one or more aspects, in the display panel 110 according to aspects of the present disclosure, the second pixel circuit SPC2 may be located in the optical bezel area OBA where the second light emitting element ED2 corresponding to the second pixel circuit SPC2 is disposed, and the third pixel circuit SPC3 may be located in the normal area NA where the third light emitting element ED3 corresponding to the third pixel circuit SPC3 is disposed.

Referring to FIG. 5, in one or more aspects, in the display panel 110 according to aspects of the present disclosure, the first pixel circuit SPC1 may not be located in the optical area OA where the first light emitting element ED1 corresponding to the first pixel circuit SPC1 is disposed. Instead, the first pixel circuit SPC1 may be located in the optical bezel area OBA located outside of the optical area OA. As a result, the transmittance of the optical area OA may be improved.

Referring to FIG. 5, in one or more aspects, the display panel 110 according to aspects of the present disclosure may further include an anode extension line AEL electrically connecting the first light emitting element ED1 disposed in the optical area OA to the first pixel circuit SPC1 disposed in the optical bezel area OBA.

The anode extension line AEL may electrically extend or connect an anode electrode AE of the first light emitting element ED1 to a second node N2 of the first driving transistor DT1 in the first pixel circuit SPC1.

As described above, in the display panel 110 according to aspects of the present disclosure, the first pixel circuit SPC1 for driving the first light emitting element ED1 disposed in the optical area OA may be disposed in the optical bezel area OBA, not in the optical area OA. Such a structure may be referred to as an anode extension structure. Likewise, the first type of the optical area OA may be also referred to as an anode extension type.

In an aspect where the display panel 110 according to aspects of the present disclosure has such an anode extension structure, all or a portion of the anode extension line AEL may be disposed in optical area OA, and the anode extension line AEL may include a transparent material, or be or include a transparent line. Accordingly, even when the anode extension line AEL for connecting the first pixel circuit SPC1 to the first light emitting element ED1 is disposed in the optical area OA, the display device or the display panel 110 according to aspects of the present disclosure may prevent the transmittance of the optical area OA from being reduced.

Referring to FIG. 5, a plurality of light emitting areas EA may further include a fourth light emitting area EA4 emitting light of the same color as the first light emitting area EA1 and included in the optical area OA

Referring to FIG. 5, the fourth light emitting area EA4 may be disposed adjacent to the first light emitting area EA1 in a row direction or a column direction.

Referring to FIG. 5, in one or more aspects, the display panel 110 according to aspects of the present disclosure may further include a fourth light emitting element ED4 disposed in the optical area OA and having the fourth light emitting area EA4, and a fourth pixel circuit SPC4 configured to drive the fourth light emitting element ED4.

Referring to FIG. 5, the fourth pixel circuit SPC4 may include a fourth driving transistor DT4. For convenience of description, a scan transistor ST and a storage capacitor Cst included in the fourth pixel circuit SPC4 are omitted from FIG. 5.

Referring to FIG. 5, although the fourth pixel circuit SPC4 is a circuit for driving the fourth light emitting element ED4 disposed in the optical area OA, the fourth pixel circuit SPC4 may be disposed in the optical bezel area OBA.

Referring to FIG. 5, in one or more aspects, the display panel 110 according to aspects of the present disclosure may further include an anode extension line AEL for electrically connecting the fourth light emitting element ED4 to the fourth pixel circuit SPC4.

All or a portion of the anode extension line AEL may be disposed in the optical area OA, and the anode extension line AEL may include a transparent material, or be or include a transparent line.

As described above, the first pixel circuit SPC1 disposed in the optical bezel area OBA may be configured to drive one light emitting element ED1 disposed in the optical area OA. Such a circuit connection scheme may be referred to as a one-to-one (1:1) circuit connection scheme.

As a result, the number of pixel circuits SPC disposed in the optical bezel area OBA may be increased significantly. Further, the structure of the optical bezel area OBA may become complicated, and an open area of the optical bezel area OBA may be reduced. Herein, the open area may be referred to as a light emitting area, and may also be referred to as an open ratio or an aperture ratio.

To increase an open area of the optical bezel area OBA while having an anode extension structure, in one or more aspects, the display device 100 according to aspects of the present disclosure may be configured in a 1:N (where N is 2 or more) circuit connection scheme.

According to the 1:N circuit connection scheme, the first pixel circuit SPC1 disposed in the optical bezel area OBA may be configured to drive two light emitting elements ED disposed in the optical area OA concurrently or together.

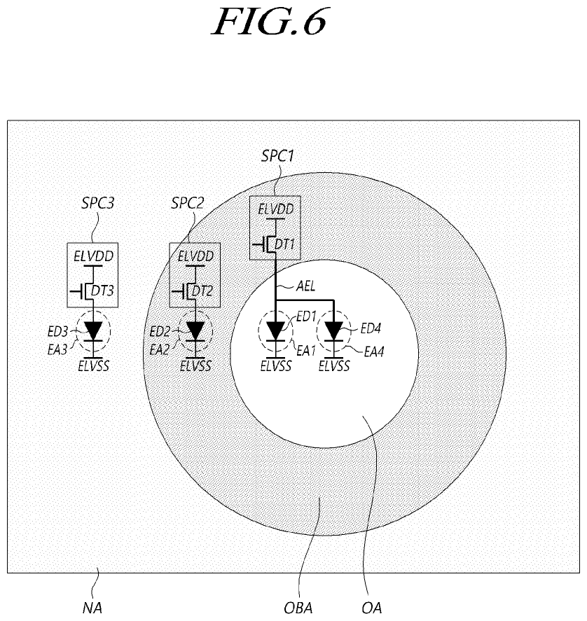

FIG. 6 illustrates a 1:2 circuit connection scheme as an example for convenience of description. In this example, a first pixel circuit SPC1 disposed in the optical bezel area OBA may be configured to drive two or more light emitting elements (ED1 and ED4) disposed in the optical area OA concurrently or together.

In one or more aspects, referring to FIG. 6, light emitting elements (ED1, ED2, ED3, and ED4) disposed in the normal area NA, the optical bezel area OBA, and the optical area OA, and pixel circuits (SPC1, SPC2, and SPC3) for driving the light emitting elements (ED1, ED2, ED3, and ED4) may be disposed in the display panel 110.

Referring to FIG. 6, a fourth light emitting element ED4 disposed in the optical area OA may be driven by the first pixel circuit SPC1 for driving a first light emitting element ED1 located in the optical area OA. That is, the first pixel circuit SPC1 disposed in the optical bezel area OBA may be configured to drive the first light emitting element ED1 and the fourth light emitting element ED4 disposed in the optical area OA together or substantially concurrently.

Accordingly, even when the display panel 110 has an anode extension structure, the number of pixel circuits SPC disposed in the optical bezel area OBA may be significantly reduced, and thereby, an open area and a light emitting area of the optical bezel area OBA may be increased.

In the example of FIG. 6, the first light emitting element ED1 and the fourth light emitting element ED4 driven together by the first pixel circuit SPC1 disposed in the optical bezel area OBA may be light emitting elements that emit light of a same color, and are adjacent to each other in a row direction or a column direction.

Referring to FIG. 6, an anode extension line AEL may connect the first light emitting element ED1 and the fourth light emitting element ED4 disposed in the optical area OA to the first pixel circuit SPC1 disposed in the optical bezel area OBA.

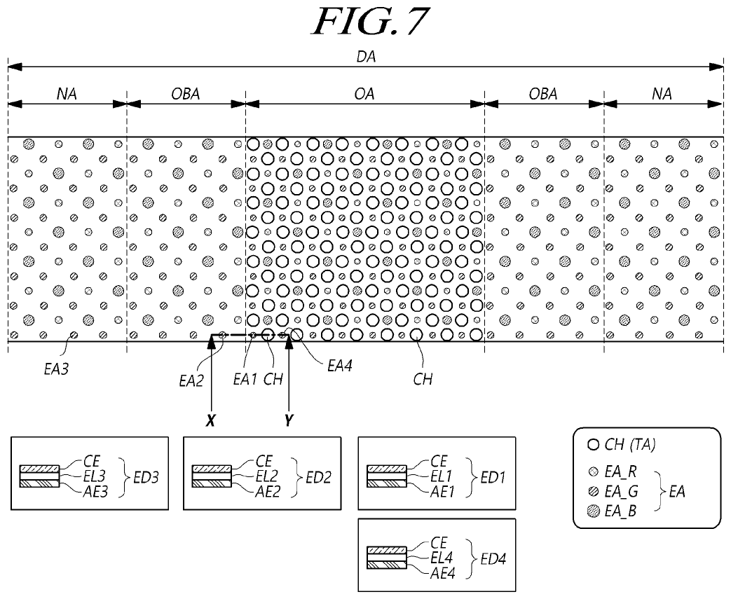

FIG. 7 is an example plan view of the normal area NA, the optical bezel area OBA, and the optical area OA in the display panel 110 according to aspects of the present disclosure.

Referring to FIG. 7, in one or more aspects, in the display panel 110 according to aspects of the present disclosure, a plurality of light emitting areas EA disposed in each of the normal area NA, the optical bezel area OBA, and the optical area OA may include a red light emitting area EA_R, a green light emitting area EA_G, and a blue light emitting area EA_B.

Referring to FIG. 7, in one or more aspects, in the display panel 110 according to aspects of the present disclosure, a cathode electrode (e.g., the cathode electrode CE of FIG. 3) may be commonly disposed in the normal area NA, the optical bezel area OBA, and the optical area OA.

The cathode electrode CE may include a plurality of cathode holes CH, and the plurality of cathode holes CH of the cathode electrode CE may be disposed in the optical area OA.

The normal area NA and the optical bezel area OBA may be areas through which light cannot be transmitted, and the optical area OA may be an area through which light may be transmitted. Accordingly, the transmittance of the optical area OA may be higher than respective transmittance of the optical bezel area OBA and the normal area NA.

All of the optical area OA may be an area through which light may be transmitted, and the plurality of cathode holes CH of the optical area OA may be transmittable areas TA through which light may be transmitted more effectively. For example, the remaining area except for the plurality of cathode holes CH in the optical area OA may be an area through which light may be transmitted, and respective transmittance of the plurality of cathode holes CH in the optical area OA may be higher than the transmittance of the remaining area except for the plurality of cathode holes (CH) in the optical area OA.

In another example, the plurality of cathode holes CH in the optical area OA may be transmission areas TA through which light may be transmitted, and the remaining area except for the plurality of cathode holes CH in the optical area OA may be an area through which light cannot be transmitted.

Referring to FIG. 7, the arrangement of light emitting areas EA in the optical area OA, the arrangement of light emitting areas EA in the optical bezel area OBA, and the arrangement of light emitting areas EA in the normal area NA may be the same as one another.

Referring to FIG. 7, a plurality of light emitting areas EA may include a first light emitting area EA1 included in the optical area OA, a second light emitting area EA2 included in the optical bezel area OBA and emitting light of the same color as the first light emitting area EA1, and a third light emitting area EA3 included in the normal area NA and emitting light of the same color as the first light emitting area EA1.

Referring to FIG. 7, the plurality of light emitting areas EA may further include a fourth light emitting area EA4 included in the optical area OA and emitting light of the same color as the first light emitting area EA1.

Referring to FIG. 7, in one or more aspects, the display panel 110 according to aspects of the present disclosure may include a first anode electrode AE1 disposed in the optical area OA, a second anode electrode AE2 disposed in the optical bezel area OBA, a third anode electrode AE3 disposed in the normal area NA, and a fourth anode electrode AE4 disposed in the optical area OA.

In one or more aspects, the display panel 110 according to aspects of the present disclosure may further include a cathode electrode (e.g., the cathode electrode CE in FIG. 3) commonly disposed in the normal area NA, the optical bezel area OBA, and the optical area OA.

In one or more aspects, the display panel 110 according to aspects of the present disclosure may include a first emission layer EL1 disposed in the optical area OA, a second emission layer EL2 disposed in the optical bezel area OBA, a third emission layer EL3 disposed in the normal area NA, and a fourth emission layer EL4 disposed in the optical area OA.

The first to fourth emission layers EL4 may be emission layers emitting light of a same color. In these aspects, the first to fourth emission layers EL1 to EL4 may be disposed as separate emission layers or be integrated into a single emission layer.

Referring to FIG. 7, light emitting elements of the display panel 110 according to aspects of the present disclosure may be configured such that: the first light emitting element ED1 is configured with the first anode electrode AE1, the first emission layer EL1, and the cathode electrode CE; the second light emitting element ED2 is configured with the second anode electrode AE2, the second emission layer EL2, and the cathode electrode CE; the third light emitting element ED3 is configured with the third anode electrode AE3, the third emission layer EL3, and the cathode electrode CE; and the fourth light emitting element ED4 is configured with the fourth anode electrode AE4, the fourth emission layer EL4, and the cathode electrode CE.

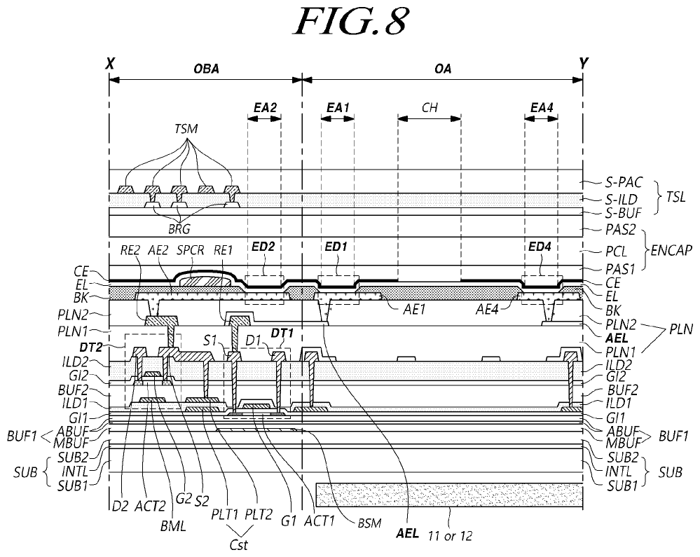

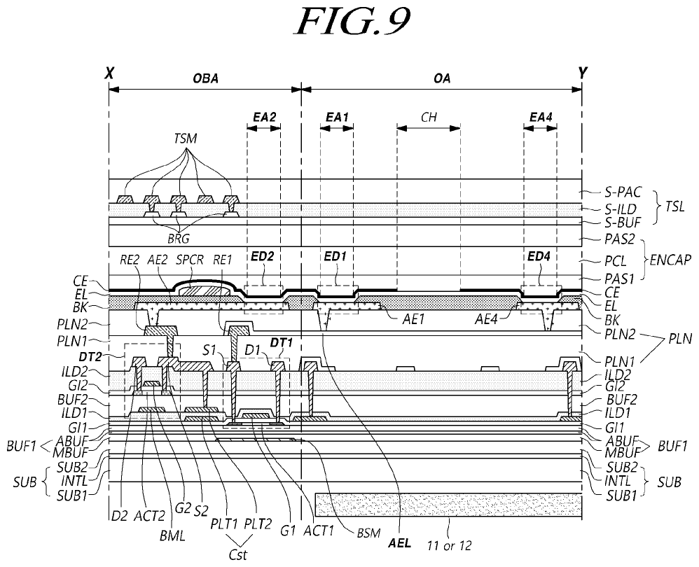

Hereinafter, a cross-sectional structure taken along line X-Y of FIG. 7 will be discussed in more detail with reference to FIGS. 8 and 9.

A portion indicated by line X-Y in FIG. 7 includes a portion of the optical bezel area OBA1 and a portion of the optical area OA1 with respect to the boundary between the optical bezel area OBA1 and the optical area OA1.

The portion indicated by line X-Y in FIG. 7 may include the first light emitting area EA1 and the fourth light emitting area EA4 included in the optical area OA, and the second light emitting area EA2 included in the optical bezel area OBA. The first light emitting area EA1, the fourth light emitting area EA4, and the second light emitting area EA2 may represent light emitting areas EA emitting light of a same color.

FIG. 8 illustrates an example cross-sectional view of the display panel 110 according to aspects of the present disclosure, and more specifically, illustrates example cross-sectional views in the optical bezel area OBA and the optical area OA of the display panel 110. It should be noted here that FIG. 8 illustrates cross-sectional views based on the application of a 1:1 circuit connection scheme, as in FIG. 5.

Referring to FIG. 8, in terms of stackup configuration, the display panel 110 may include a transistor forming part, a light emitting element forming part, and an encapsulation part.

The transistor forming part may include a substrate SUB, a first buffer layer BUF1 on the substrate SUB, various types of transistors DT1 and DT2 formed on the first buffer layer BUF, a storage capacitor Cst, and various electrodes and signal lines.

The substrate SUB may include, for example, a first substrate SUB1 and a second substrate SUB2, and may include an intermediate layer INTL interposed between the first substrate SUB1 and the second substrate SUB2. In this example, the intermediate layer INTL may be an inorganic layer and may serve to prevent moisture permeation.

A lower shield metal BSM may be disposed over the substrate SUB. The lower shield metal BSM may be located under a first active layer ACT1 of a first driving transistor DT1.

The first buffer layer BUF1 may include a stack of a single layer or a stack of multiple layers. In an example where the first buffer layer BUF1 includes a stack of multiple layers, the first buffer layer BUF1 may include a multi-buffer layer MBUF and an active buffer layer ABUF.

Various types of transistors (DT1, DT2, and the like), at least one storage capacitor Cst, and various electrodes or signal lines may be disposed on the first buffer layer BUF1.

For example, the transistors DT1 and DT2 formed on the first buffer layer BUF1 may include a same material, and be located in one or more same layers. In another example, as shown in FIG. 8, the first driving transistor DT1 and a second driving transistor DT2 among the transistors (DT1, DT2, and the like) may include different materials and be located in different layers.

Referring to FIG. 8, the first driving transistor DT1 may represent a driving transistor DT for driving the first light emitting element ED1 included in the optical area OA, and the second driving transistor DT2 may represent a driving transistor DT for driving the second light emitting element ED2 included in the optical bezel area OBA.

For example, the first driving transistor DT1 may represent a driving transistor included in the first pixel circuit SPC1 for driving the first light emitting element ED1 included in the optical area OA, and the second driving transistor DT2 may represent a driving transistor included in the second pixel circuit SPC2 for driving the second light emitting element ED2 included in the optical bezel area OBA.

Stackup configurations of the first driving transistor DT1 and the second driving transistor DT2 will be described below.

The first driving transistor DT1 may include the first active layer ACT1, a first gate electrode G1, a first source electrode S1, and a first drain electrode D1.

The second driving transistor DT2 may include a second active layer ACT2, a second gate electrode G2, a second source electrode S2, and a second drain electrode D2.

The second active layer ACT2 of the second driving transistor DT2 may be located in a higher location in the stackup configuration than the first active layer ACT1 of the first driving transistor DT1.

The first buffer layer BUF1 may be disposed under the first active layer ACT1 of the first driving transistor DT1, and the second buffer layer BUF2 may be disposed under the second active layer ACT2 of the second driving transistor DT2.

For example, the first active layer ACT1 of the first driving transistor DT1 may be located on the first buffer layer BUF1, and the second active layer ACT2 of the second driving transistor DT2 may be located on the second buffer layer BUF2. In this case, the second buffer layer BUF2 may be placed in a higher location than the first buffer layer BUF.

The first active layer ACT1 of the first driving transistor DT1 may be disposed on the first buffer layer BUF1, and a first gate insulating layer GI1 may be disposed on the first active layer ACT1 of the first driving transistor DT1. The first gate electrode G1 of the first driving transistor DT1 may be disposed on the first gate insulating layer GI1, and a first interlayer insulating layer ILD1 may be disposed on the first gate electrode G1 of the first driving transistor DT1.

In this implementation, the first active layer ACT1 of the first driving transistor DT1 may include a first channel region overlapping with the first gate electrode G1, a first source connection region located on one side of the first channel region, and a first drain connection region located on the other side of the first channel region.

The second buffer layer BUF2 may be disposed on the first interlayer insulating layer ILD1.

The second active layer ACT2 of the second driving transistor DT2 may be disposed on the second buffer layer BUF2, and a second gate insulating layer GI2 may be disposed on the second active layer ACT2. The second gate electrode G2 of the second driving transistor DT2 may be disposed on the second gate insulating layer GI2, and a second interlayer insulating layer ILD2 may be disposed on the second gate electrode G2.

In this implementation, the second active layer ACT2 of the second driving transistor DT2 may include a second channel region overlapping with the second gate electrode G2, a second source connection region located on one side of the second channel region, and a second drain connection region located on the other side of the second channel region.

The first source electrode S1 and the first drain electrode D1 of the first driving transistor DT1 may be disposed on the second interlayer insulating layer ILD2. The second source electrode S2 and the second drain electrode D2 of the second driving transistor DT2 may be also disposed on the second interlayer insulating layer ILD2.

The first source electrode S1 and the first drain electrode D1 of the first driving transistor DT1 may be respectively connected to the first source connection region and the first drain connection region of the first active layer ACT1 through through-holes formed in the second interlayer insulating layer ILD2, the second gate insulating layer GI2, the second buffer layer BUF2, the first interlayer insulating layer ILD1, and the first gate insulating layer GI1.

The second source electrode S2 and the second drain electrode D21 of the second driving transistor DT2 may be respectively connected to the second source connection region and the second drain connection region of the second active layer ACT2 through through-holes formed in the second interlayer insulating layer ILD2 and the second gate insulating layer GI2.

It should be understood that FIG. 8 illustrates only the second driving transistor DT2 and a storage capacitor Cst among circuit components included in the second pixel circuit SPC2, and other components such as one or more transistors, and the like are omitted. It should be also understood that FIG. 8 illustrates only the first driving transistor DT1 among circuit components included in the first pixel circuit SPC1, and other components such as one or more transistors, a storage capacitor, and the like are omitted.

Referring to FIG. 8, the storage capacitor Cst included in the second pixel circuit SPC2 may include a first capacitor electrode PLT1 and a second capacitor electrode PLT2.

The first capacitor electrode PLT1 may be electrically connected to the second gate electrode G2 of the second driving transistor DT2, and the second capacitor electrode PLT2 may be electrically connected to the second source electrode S2 of the second driving transistor DT2.

In one or more aspects, referring to FIG. 8, a lower metal BML may be disposed under the second active layer ACT2 of the second driving transistor DT2. This lower metal BML may overlap with all or a portion of the second active layer ACT2.

The lower metal BML may be electrically connected to, for example, the second gate electrode G2. In another example, the lower metal BML may serve as a light shield for shielding light traveling from a lower location than the lower metal BML. In this implementation, the lower metal BML may be electrically connected to the second source electrode S2.

Even though the first driving transistor DT1 is a transistor for driving the first light emitting element ED1 disposed in the optical area OA, the first driving transistor DT1 may be disposed in the optical bezel area OBA, not the optical area OA.

The second driving transistor DT2, which is a transistor for driving the second light emitting element ED2 disposed in the optical bezel area OBA, may be disposed in the optical bezel area OBA.

Referring to FIG. 8, the display panel 110 may include at least one planarization layer PLN disposed on the first driving transistor DT1 and the second driving transistor DT2.

Referring to FIG. 8, for example, the at least one planarization layer PLN may include a first planarization layer PLN1. For example, the first planarization layer PLN1 may be disposed on the first source electrode S1 and the first drain electrode D1 of the first driving transistor DT1 and the second source electrode S2 and the second drain electrode D2 of the second driving transistor DT2.

Referring to FIG. 8, a first relay electrode RE1 and a second relay electrode RE2 may be disposed on the first planarization layer PLN1.

The first relay electrode RE1 may represent an electrode for relaying an electrical interconnection between the first source electrode S1 of the first driving transistor DT1 and a first anode electrode AE1 of the first light emitting element ED1. The second relay electrode RE2 may represent an electrode for relaying an electrical interconnection between the second source electrode S2 of the second driving transistor DT2 and a second anode electrode AE2 of the second light emitting element ED2.

The first relay electrode RE1 may be electrically connected to the first source electrode S1 of the first driving transistor DT1 through a hole formed in the first planarization layer PLN1. The second relay electrode RE2 may be electrically connected to the second source electrode S2 of the second driving transistor DT2 through another hole formed in the first planarization layer PLN1.

Referring to FIG. 8, the first relay electrode RE2 and the second relay electrode RE2 may be disposed in the optical bezel area OBA.

Referring to FIG. 8, an anode extension line AEL may be connected to the first relay electrode RE1 and extend from the optical bezel area OBA to the optical area OA.

In one or more aspects, referring to FIG. 8, the anode extension line AEL may be a metal layer disposed on the first relay electrode RE1 and include a transparent material.

Referring to FIG. 8, the at least one planarization layer PLN disposed on the display panel 110 may further include a second planarization layer PLN2 on the first planarization layer PLN1.

For example, the second planarization layer PLN2 may be disposed such that the second planarization layer PLN2 covers the first relay electrode RE1, the second relay electrode RE2, and the anode extension line AEL located on the first planarization layer PLN1.

Although FIG. 8 illustrates the example where the at least one planarization layer PLN includes the first planarization layer PLN1 and the second planarization layer PLN2, aspects of the present disclosure are not limited thereto. For example, the planarization layer PLN may include only one planarization layer PLN.

Referring to FIG. 8, the light emitting element forming part may be located on the second planarization layer PNL2.

Referring to FIG. 8, the light emitting element forming part may include the first light emitting element ED1, the second light emitting element ED2, and the fourth light emitting element ED4, which are disposed on the second planarization layer PNL2.

Referring to FIG. 8, the first light emitting element ED1 and the fourth light emitting element ED4 may be disposed in the optical area OA, and the second light emitting element ED2 may be disposed in the optical bezel area OBA.

In the example of FIG. 8, the first light emitting element ED1, the second light emitting element ED2, and the fourth light emitting element ED4 may be light emitting elements emitting light of a same color. Respective emission layers EL of the first light emitting element ED1, the second light emitting element ED2, and the fourth light emitting element ED4 may be formed independently of one another. However, in discussions that follow, for convenience of explanation, it is assumed that respective emission layers EL of the first light emitting element ED1, the second light emitting element ED2, and the fourth light emitting element ED4 are commonly formed as one common emission layer.

Referring to FIG. 8, the first light emitting element ED1 may be configured (i.e., made up) in an area where the first anode electrode AE1, the emission layer EL, and the cathode electrode CE overlap with one another. The second light emitting element ED2 may be configured (i.e., made up) in an area where the second anode electrode AE2, the emission layer EL, and the cathode electrode CE overlap with one another. The fourth light emitting element ED4 may be configured (i.e., made up) in an area where the fourth anode electrode AE4, the emission layer EL, and the cathode electrode CE overlap with one another.

Referring to FIG. 8, the first anode electrode AE1, the second anode electrode AE2, and the fourth anode electrode AE4 may be disposed on the second planarization layer PLN2.

The second anode electrode AE2 may be connected to the second relay electrode RE2 through a hole formed in the second planarization layer PLN2.

The first anode electrode AE1 may be connected to an anode extension line AEL extending from the optical bezel area OBA to the optical area OA through another hole formed in the second planarization layer PLN2.

The fourth anode electrode AE4 may be connected to another anode extension line AEL extending from the optical bezel area OBA to the optical area OA through further another hole formed in the second planarization layer PLN2.

Referring to FIG. 8, a bank BK may be disposed on the first anode electrode AE1, the second anode electrode AE2, and the fourth anode electrode AE4.

The bank BK may include a plurality of bank holes, and respective portions of the first anode electrode AE1, the second anode electrode AE2, and the fourth anode electrode AE4 may be exposed through respective bank holes. That is, the plurality of bank holes formed in the bank BK may respectively overlap with the respective portions of the first anode electrode AE1, the second anode electrode AE2, and the fourth anode electrode AE4.

Referring to FIG. 8, the emission layer EL may be disposed on the bank BK. The emission layer EL may contact the respective portions of the first anode electrode AE1, the second anode electrode AE2, and the fourth anode electrode AE4 through the plurality of bank holes.

Referring to FIG. 8, at least one spacer SPCR may be present between the emission layer EL and the bank BK.

Referring to FIG. 8, the cathode electrode CE may be disposed on the emission layer EL. The cathode electrode CE may include a plurality of cathode holes CH. The plurality of cathode holes CH formed in the cathode electrode CE may be disposed in the optical area OA.

One cathode hole CH illustrated in FIG. 8 may represent a cathode hole located between the first light emitting area EA1 and the fourth light emitting area EA4.

Referring to FIG. 8, the encapsulation part may be located on the cathode electrode CE. The encapsulation part may include an encapsulation layer ENCAP disposed on the cathode electrode CE.

Referring to FIG. 8, the encapsulation layer ENCAP may serve to prevent penetration of moisture or oxygen into the light emitting elements (ED1, ED2, and ED4) disposed under the encapsulation layer ENCAP. In particular, the encapsulation layer ENCAP may include an organic material or film and may serve to prevent penetration of moisture or oxygen into the emission layer EL. In one or more aspects, the encapsulation layer ENCAP may include a stack of a single layer or a stack of a multilayer.

Referring to FIG. 8, the encapsulation layer ENCAP may include a first encapsulation layer PAS1, a second encapsulation layer PCL, and a third encapsulation layer PAS2.

For example, the first encapsulation layer PAS1 and the third encapsulation layer PAS2 may be inorganic material layers, and the second encapsulation layer PCL may be an organic material layer. Since the second encapsulation layer PCL is implemented using an organic material, the second encapsulation layer PCL may serve as a planarization layer.

In one or more aspects, a touch sensor may be integrated into the display panel 110 according to aspects of the present disclosure. In these aspects, the display panel 110 according to aspects of the present disclosure may include a touch sensor layer TSL disposed on the encapsulation layer ENCAP.

Referring to FIG. 8, the touch sensor layer TSL may include touch sensor metals TSM and bridge metals BRG, and may further include one or more insulating layers such as a sensor buffer layer S-BUF, a sensor interlayer insulating layer S-ILD, a sensor protective layer S-PAC, and the like. For example, the sensor interlayer insulating layer S-ILD may include one or more insulating layers.

The sensor buffer layer S-BUF may be disposed on the encapsulation layer ENCAP. The bridge metals BRG may be disposed on the sensor buffer layer S-BUF, and the sensor interlayer insulating layer S-ILD may be disposed on the bridge metals BRG.

The touch sensor metals TSM may be disposed on the sensor interlayer insulating layer S-ILD. One or more of the touch sensor metals TSM may be connected to one or more respective bridge metals BRG of the bridge metals BRG through one or more respective holes formed in the sensor interlayer insulating layer S-ILD.

Referring to FIG. 8, the touch sensor metals TSM and the bridge metals BRG may be disposed in the optical bezel area OBA. The touch sensor metals TSM and the bridge metals BRG may be disposed not to overlap with the second light emitting area EA2 of the optical bezel area OBA.

A plurality of touch sensor metals TSM may be configured as one touch electrode (or one touch electrode line). For example, the plurality of touch sensor metals TSM may be arranged in a mesh pattern and therefore electrically connected to one another. One or more of the touch sensor metals TSM and the remaining one or more touch sensor metals TSM may be electrically connected through one or more respective bridge metals BRG, and thereby, be configured as one touch electrode (or one touch electrode line).

The sensor protective layer S-PAC may be disposed such that it covers the touch sensor metals TSM and the bridge metals BRG.

In an aspect where a touch sensor is integrated into the display panel 110, at least one of the touch sensor metals TSM, or at least a portion of at least one of the touch sensor metals TSM, located on the encapsulation layer ENCAP may extend along an inclined surface formed in an edge of the encapsulation layer ENCAP, and be electrically connected to a pad located in an edge of the display panel 110 that is further away from the inclined surface of the edge of the encapsulation layer ENCAP. The pad may be disposed in the non-display area NDA and may be a metal pattern to which the touch driving circuit 260 is electrically connected.

The display panel 110 according to aspects of the present disclosure may include the bank BK disposed on the first anode electrode AE1 and having a bank hole exposing a portion of the first anode electrode AE1, and the emission layer EL disposed on the bank BK and contacting the portion of the first anode electrode AE1 exposed through the bank hole.

The bank hole formed in the bank BK may not overlap with a plurality of cathode holes CH. For example, the bank BK may not be depressed or perforated (i.e., remain in a flat or level state) at places where the plurality of cathode holes CH are present. Thus, at places where the plurality of cathode holes CH are present, the second planarization layer PLN and the first planarization layer PLN1 located under the bank BK may not be depressed or perforated as well (i.e., remain in a flat or level state).

The flat state of the respective portion of the upper surface of the bank BK located under any one of the plurality of cathode holes CH may mean that one or more insulating layers or one or more metal patterns (e.g., one or more electrode, one or more lines, and/or the like), or the emission layers EL located under any one of the plurality of cathode holes CH have not been damaged by the process of forming the plurality of cathode holes CH in the cathode electrode CE.

A brief description for the process of forming cathode holes CH in the cathode electrode CE is as follows. A specific mask pattern may be deposited at respective locations where the cathode holes CH are to be formed, and then, a cathode electrode material may be deposited thereon. Accordingly, the cathode electrode material may be deposited only in an area where the specific mask pattern is not located, and thereby, the cathode electrode CE including the cathode holes CH may be formed. The specific mask pattern may include, for example, an organic material. The cathode electrode material may include a magnesium-silver (Mg—Ag) alloy.

In one or more aspects, after the cathode electrode CE having the cathode holes CH is formed, the display panel 110 may be in a situation in which the specific mask pattern is completely removed, partially removed (where a portion of the specific mask pattern remains), or not removed (where all of the specific mask pattern remains without being removed).

In one or more aspects, the display panel 110 according to aspects of the present disclosure may include the first driving transistor DT1 disposed in the optical bezel area OBA to drive the first light emitting element ED1 disposed in the optical area OA, and the second driving transistor DT2 disposed in the optical bezel area OBA to drive the second light emitting element ED2 disposed in the optical bezel area OBA.

In one or more aspects, the display panel 110 according to aspects of the present disclosure may further include the first planarization layer PLN1 disposed on the first driving transistor DT1 and the second driving transistor DT2, the first relay electrode RE1 disposed on the first planarization layer PLN1 and electrically connected to the first source electrode S1 of the first driving transistor DT1 through a hole formed in the first planarization layer PLN1, the second relay electrode RE2 disposed on the first planarization layer PLN1 and electrically connected to the second source electrode S2 of the second driving transistor DT2 through another hole formed in the first planarization layer PLN1, and the second planarization layer PLN2 disposed on the first relay electrode RE1 and the second relay electrode RE2.

In one or more aspects, the display panel 110 according to aspects of the present disclosure may further include an anode extension line (e.g., the anode extension line AEL) interconnecting the first relay electrode RE1 and the first anode electrode AE1, and located on the first planarization layer PLN1.

The second anode electrode AE2 may be electrically connected to the second relay electrode RE2 through a hole formed in the second planarization layer PLN2, and the first anode electrode AE1 may be electrically connected to the anode extension line AEL through another hole formed in the second planarization layer PLN2.

All or a portion of the anode extension line AEL may be disposed in the optical area OA, and the anode extension line AEL may include a transparent material, or be or include a transparent line.

The first pixel circuit SPC1 may include the first driving transistor DT1 for driving the first light emitting element ED1, and the second pixel circuit SPC2 may include the second driving transistor DT2 for driving the second light emitting element ED2.

The first active layer ACT1 of the first driving transistor DT1 may be located in a different layer from the second active layer ACT2 of the second driving transistor DT2.

In one or more aspects, the display panel 110 according to aspects of the present disclosure may further include the substrate SUB, the first buffer layer BUF1 disposed between the substrate SUB and the first driving transistor DT1, and the second buffer layer BUF2 disposed between the first driving transistor DT1 and the second driving transistors DT2.

The first active layer ACT1 of the first driving transistor DT1 may include a different semiconductor material from the second active layer ACT2 of the second driving transistor DT2.

For example, the second active layer ACT2 of the second driving transistor DT2 may include an oxide semiconductor material. For example, such an oxide semiconductor material may include indium gallium zinc oxide (IGZO), indium gallium zinc tin oxide (IGZTO), zinc oxide (ZnO), cadmium oxide (CdO), indium oxide (InO), zinc tin oxide (ZTO), zinc indium tin oxide (ZITO), and/or the like.

For example, the first active layer ACT1 of the first driving transistor DT1 may include a different semiconductor material from the second active layer ACT2 of the second driving transistor DT2.

For example, the first active layer ACT1 of the first driving transistor DT1 may include a silicon-based semiconductor material. For example, the silicon-based semiconductor material may include low-temperature polycrystalline silicon (LTPS) or the like.

In one or more aspects, the display panel 110 according to aspects of the present disclosure may further include the encapsulation layer ENCAP located on the first light emitting element ED1, the second light emitting element ED2, and the third light emitting element ED3, and touch sensor metals TSM located on the encapsulation layer ENCAP.

The touch sensor metals TSM may be disposed in the normal area NA and the optical bezel area OBA. For example, the touch sensor metals TSM may not be disposed in the optical area OA. In another example, the touch sensor metals TSM may be disposed in the optical area OA, the normal area NA and the optical bezel area OBA such that the optical area OA has a lower touch sensor metal density than each of the normal area NA and the optical bezel area OBA.

Referring to FIG. 8, the optical area OA may overlap with an optical electronic device. The optical bezel area OBA may not overlap with an optical electronic device. One or more aspects, a portion of the optical bezel area OBA may overlap with an optical electronic device.

The optical electronic device overlapping with the optical area OA may be the first optical electronic device 11 and/or the second optical electronic device 12 discussed above. For example, the optical electronic device may include a camera, an infrared sensor, an ultraviolet sensor, and/or the like. For example, the optical electronic device may be a device capable of receiving visible light and performing a predetermined operation, or a device capable of receiving light (e.g., infrared light, and/or ultraviolet light) different from visible light and performing a predetermined operation.

Referring to FIG. 8, a cross-sectional structure of the normal area NA may be substantially or nearly the same as that of the optical bezel area OBA. It should be noted here that the first pixel circuit SPC1 disposed in the optical bezel area OBA to drive the first light emitting element ED1 disposed in the optical area OA may not be disposed in the normal area NA.

FIG. 9 illustrates an example cross-sectional view of the display panel 110 according to aspects of the present disclosure, and more specifically, illustrates example cross-sectional views in the optical bezel area OBA and the optical area OA of the display panel 110. It should be noted here that FIG. 9 illustrates an example cross-sectional view based on the application of a 1:2 circuit connection scheme, as in FIG. 6.

The cross-sectional view of FIG. 9 is basically the same as the cross-sectional view of FIG. 8. It should be noted here that one difference between the cross-sectional views of FIGS. 8 and 9 is that while FIG. 8 employs the 1:1 circuit connection scheme as in FIG. 5, FIG. 9 employs the 1:2 circuit connection scheme as in FIG. 6. Taking account of the similarity between them, hereinafter, descriptions on the cross-sectional structure of FIG. 9 will be provided by focusing on features different from the cross-sectional structure of FIG. 8.

Referring to FIG. 9, the first light emitting element ED1 and the fourth light emitting element ED4 disposed in the optical area OA may be driven by the first driving transistor DT1 disposed in the optical bezel area OBA together or substantially concurrently.

Accordingly, as illustrated in FIG. 9, an anode extension line AEL (e.g., the anode extension line AEL of FIG. 8) may be further electrically connected to the fourth anode electrode AE4 different from the first anode electrode AE1, as well as the first anode electrode AE1. Thus, the anode extension line AEL may be electrically connected to both the first anode electrode AE1 of the first light emitting element ED1 and the fourth anode electrode AE4 of the fourth light emitting element ED4.

Referring to FIG. 9, the anode extension line AEL may overlap with a cathode hole CH located between the first light emitting element ED1 and the fourth light emitting element ED4 among a plurality of cathode holes CH.

Referring to FIG. 9, the first light emitting area EA1 configured by the first light emitting element ED1 and the fourth light emitting area EA4 configured by the fourth light emitting element ED4 may be light emitting areas emitting light of a same color.

For example, in the optical area OA, an area except for a plurality of cathode holes CH, which are the transmittable areas TA, may be an area through which light cannot be transmitted. In another example, in the optical area OA, the area except for the plurality of cathode holes CH, which are the transmittable areas TA, may be an area through which light may be transmitted with a low transmittance (or a low transmissivity).

Thus, in the optical area OA, the transmittance (or transmissivity) of the area except for the plurality of cathode holes CH, which are the transmittable areas TA, may be lower than that of the plurality of cathode holes CH, which are the transmittable areas TA. In one or more aspects, the transmittance (or transmissivity) of the area except for the plurality of cathode holes CH, which are the transmittable areas TA, in the optical area OA may be higher than that of the normal area NA.

FIG. 10 schematically illustrates an example second type of optical area OA and an example normal area NA around the second type of optical area OA in the display panel 110 according to aspects of the present disclosure.

Referring to FIG. 10, the display area DA may include an optical area OA. The optical area OA may have the structure of a second type. In an example where the second type of optical area OA is implemented in the second type, the optical area OA may include a plurality of transmission areas TA and a low-transmittable area LTA (also known as a low-transmission area and having a lower optical transmission than the transmission areas TA). The second type of the optical area OA may be also referred to as a hole type.

Referring to FIG. 10, in the optical area OA, the low-transmittable area LTA except for the plurality of transmission areas TA may include a plurality of light emitting areas EA. In the optical area OA, a plurality of light emitting elements ED for the plurality of light emitting areas EA may be disposed in the low-transmittable area LTA except for the plurality of transmission areas TA.

Further, a plurality of pixel circuits SPC for driving the plurality of light emitting elements ED may be disposed in the low-transmittable area LTA. That is, the plurality of pixel circuits SPC may be disposed in the optical area OA. This is different from the first type (i.e., the anode extension type) of the optical area OA in the examples of FIGS. 4 to 9 in which the plurality of pixel circuits SPC are not disposed in the optical area OA.

In one aspect, the low-transmittable area LTA in the optical area OA may be an area through which light cannot be transmitted. In another aspect, the low-transmittable area LTA in the optical area OA may be an area through which light may be transmitted with a low transmittance (or a low transmissivity).

In the optical area OA, the transmittance (or transmissivity) of the low-transmittable area LTA may be lower than that of the transmission area TA. In one or more aspects, the transmittance (or transmissivity) of the low-transmittable area LTA in the optical area OA may be higher than that of the normal area NA.

Referring to FIG. 10, the arrangement of light emitting areas EA in the optical area OA may be the same as the arrangement of light emitting areas EA in the normal area NA.

In one or more aspects, referring to FIG. 10, a respective area of each of a plurality of light emitting areas EA included in the optical area OA may be the same or substantially or nearly the same as, or be different within a predetermined range from, a respective area of each of a plurality of light emitting areas EA included in the normal area NA.

In addition, the area of each of the plurality of light emitting areas EA included in the optical area OA may be the same or different within a predetermined range.

A cathode electrode (e.g., the cathode electrode CE in FIG. 3) may be commonly disposed in the normal area NA and the optical area OA, and may include a plurality of cathode holes CH in the optical area OA. The plurality of cathode holes CH of the cathode electrode CE may respectively correspond to the transmission areas TA of the optical area OA.

Since the optical area OA includes the plurality of transmission areas TA, the optical area OA may have higher transmittance than the normal area NA.

All or a portion of the optical area OA may overlap with an optical electronic device.

The optical electronic device overlapping with the optical area OA may be the first optical electronic device 11 and/or the second optical electronic device 12 discussed above. For example, the optical electronic device may include a camera, an infrared sensor, an ultraviolet sensor, and/or the like. For example, the optical electronic device may be a device capable of receiving visible light and performing a predetermined operation, or a device capable of receiving light (e.g., infrared light, and/or ultraviolet light) different from visible light and performing a predetermined operation.

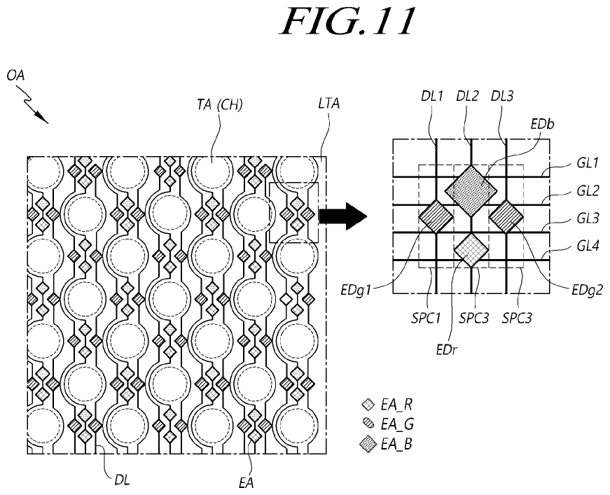

FIG. 11 is an example plan view of the second type of optical area OA (e.g., as in the configuration of the FIG. 10) in the display panel 110 according to aspects of the present disclosure.

Referring to FIG. 11, in an example where the optical area OA is implemented in the second type, the optical area OA may include one or more transmission areas TA and a low-transmittable area LTA except for the one or more transmission areas.

The low-transmittable area LTA may include a plurality of light emitting areas EA.

A respective light emitting element ED may be disposed in each of the plurality of light emitting areas EA.

A plurality of pixel circuits SPC for driving the plurality of light emitting elements ED may be disposed in the low-transmittable area LTA.

In the second type of optical area OA, the light emitting elements ED and the pixel circuits SPC may partially overlap with each other.

In the case of the second type of optical area OA, data lines (DL1, DL2 and DL3) and gate lines (GL1, GL2, GL3, and GL4) may run across the optical area OA.

In the optical area OA, the data lines (DL1, DL2 and DL3) may be arranged in a row direction (or a column direction) while avoiding one or more transmission areas TA, which correspond to one or more respective cathode holes CH.

In the optical area OA, the gate lines (GL1, GL2, GL3, and GL4) may be arranged in the column direction (or the row direction) while avoiding one or more transmission areas TA, which correspond to one or more respective cathode holes CH.

The data lines (DL1, DL2 and DL3) and the gate lines (GL1, GL2, GL3, and GL4) may be connected to pixel circuits (SPC1, SPC2, and SPC3) disposed in the optical area OA.

For example, four light emitting elements (EDr, EDg1, EDg2, and EDb) may be disposed in a portion of the low-transmittable area LTA between four adjacent transmission areas TA. The four light emitting elements (EDr, EDg1, EDg2, and EDb) may include one red light emitting element EDr, two green light emitting elements EDg1 and EDg2, and one blue light emitting element EDb.

For example, a pixel circuit SPC1 for driving the one red light emitting element EDR may be connected to a first data line DL1 and a first gate line GL1. A pixel circuit SPC2 for driving the two green light emitting elements EDg1 and EDg2 may be connected to a second data line DL2, a second gate line GL2, and a third gate line GL3. A pixel circuit SPC3 for driving the one blue light emitting element EDb may be connected to a third data line DL3 and a fourth gate line GL4.

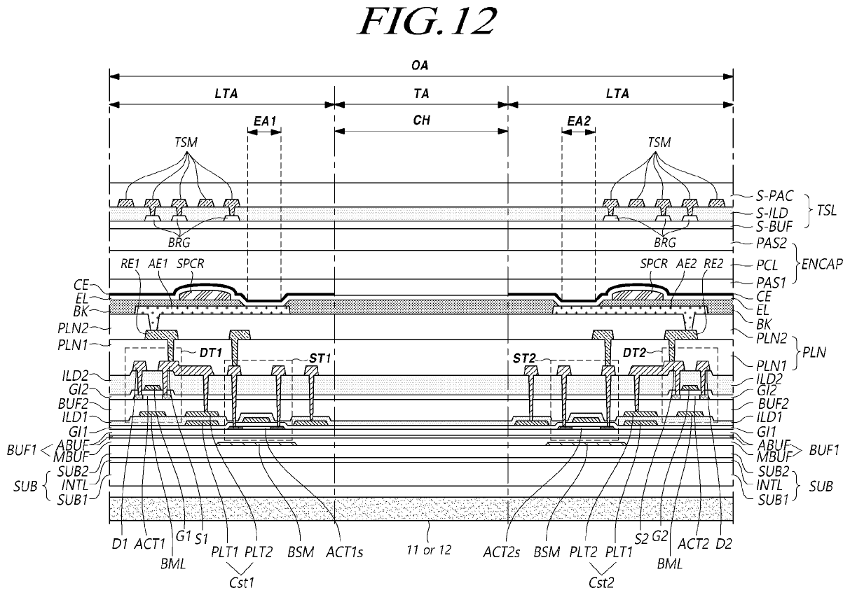

FIG. 12 is an example cross-sectional view of the second type of optical area OA (e.g., as in the configuration of FIGS. 10 and 11) in the display panel 110 according to aspects of the present disclosure.

Metal layers and insulating layers in the cross-sectional structure of FIG. 12 may be the same, or substantially or nearly the same, as the metal layers and insulating layers in the cross-sectional structures of FIGS. 8 and 9. Taking account of the similarity between them, discussions on the cross-sectional structure of FIG. 12 will be provided by focusing on features different from those of the cross-sectional structures of FIGS. 8 and 9.

Referring to FIG. 12, an optical electronic device may be disposed such that it overlap with all or a portion of the optical area OA. The optical electronic device may be the first optical electronic device 11 and/or the second optical electronic device 12 discussed above.

Referring to FIG. 12, a first light emitting element ED1 and a second light emitting element ED2 may be disposed in the optical area OA. A first light emitting area EA1 configured by the first light emitting element ED1 and a second light emitting area EA2 configured by the second light emitting element ED2 may be light emitting areas emitting light of a same color.

Referring to FIG. 12, an area where the first light emitting element ED1 and the second light emitting element ED2 are disposed may be a low-transmittable area LTA, and a transmission area TA may be present between the first light emitting element ED1 and the second light emitting element ED2. That is, the transmission area TA may be present between the first light emitting area EA1 configured by the first light emitting element ED1 and the second light emitting area EA2 configured by the second light emitting element ED2.

A pixel circuit SPC may be configured to drive the first light emitting element ED1, and be disposed to overlap with all or a portion of the first light emitting element ED1 in the optical area OA.

Referring to FIG. 12, the pixel circuit SPC for driving the first light emitting element ED1 may include a first driving transistor DT1, a first scan transistor ST1, and a first storage capacitor Cst1.

A pixel circuit SPC may be configured to drive the second light emitting element ED2, and be disposed to overlap with all or a portion of the second light emitting element ED2 in the optical area OA.

Referring to FIG. 12, the pixel circuit SPC for driving the second light emitting element ED2 may include a second driving transistor DT2, a second scan transistor ST2, and a second storage capacitor Cst2.

Referring to FIG. 12, the first driving transistor DT1 may include a first active layer ACT1, a first gate electrode G1, a first source electrode S1, and a first drain electrode D1.

The first light emitting element ED1 may be configured (i.e., made up) in an area where a first anode electrode AE1, an emission layer (e.g., the emission layer EL discussed above), and a cathode electrode (e.g., the cathode electrode CE discussed above) overlap with one another.

The first source electrode S1 of the first driving transistor DT1 may be connected to the first anode electrode AE1 through a first relay electrode RE1.

The first storage capacitor Cst1 may include a first capacitor electrode PLT1 and a second capacitor electrode PLT2.

The first source electrode S1 of the first driving transistor DT1 may be connected to the second capacitor electrode PLT2 of the first storage capacitor Cst1.

The first gate electrode G1 of the first driving transistor DT1 may be connected to the first capacitor electrode PLT1 of the first storage capacitor Cst1.

The active layer ACT1s of the first scan transistor ST1 may be located on the first buffer layer BUF1 and be located in a lower location than the first active layer ACT1 of the first driving transistor DT1.

A semiconductor material included in the active layer ACT1s of the first scan transistor ST1 may be different from a semiconductor material included in the first active layer ACT1 of the first driving transistor DT1. For example, the semiconductor material included in the first active layer ACT1 of the first driving transistor DT1 may be an oxide semiconductor material, and the semiconductor material included in the active layer ACT1s of the first scan transistor ST1 may be a silicon-based semiconductor material (e.g., a low-temperature polycrystalline silicon (LTPS)).

Referring to FIG. 12, the second driving transistor DT2 may include a second active layer ACT2, a second gate electrode G2, a second source electrode S2, and a second drain electrode D2.

The second light emitting element ED2 may be configured (i.e., made up) in an area where a second anode electrode AE2, the emission layer EL, and the cathode electrode CE overlap with one another.

The second source electrode S2 of the second driving transistor DT2 may be connected to the second anode electrode AE2 through a second relay electrode RE2.

The second storage capacitor Cst2 may include a first capacitor electrode PLT1 and a second capacitor electrode PLT2.

The second source electrode S2 of the second driving transistor DT1 may be connected to the second capacitor electrode PLT2 of the second storage capacitor Cst2.

The second gate electrode G2 of the second driving transistor DT2 may be connected to the first capacitor electrode PLT1 of the second storage capacitor Cst2.

An active layer ACT2s of the second scan transistor ST2 may be located on the first buffer layer BUF1 and be located in a lower location than the second active layer ACT2 of the second driving transistor DT2.

A semiconductor material included in the active layer ACT2s of the second scan transistor ST2 may be different from a semiconductor material included in the second active layer ACT2 of the second driving transistor DT2. For example, the semiconductor material included in the second active layer ACT2 of the second driving transistor DT2 may be an oxide semiconductor material, and the semiconductor material included in the active layer ACT2s of the second scan transistor ST2 may be a silicon-based semiconductor material (e.g., a low-temperature polycrystalline silicon (LTPS)).

The cathode electrode CE may not include a cathode hole CH or may include a plurality of cathode holes CH.

In an example where the cathode electrode CE includes a plurality of cathode holes CH, the cathode holes CH formed in the cathode electrode CE may be located to correspond to respective transmission areas TA of the optical area OA.

A bank hole formed in the bank BK may not overlap with any one of the cathode holes CH.

An upper surface of the bank BK located in a lower location than the cathode holes CH may be flat without being depressed or etched. For example, the bank BK may not be depressed or perforated (i.e., remain in the flat state) at places where the plurality of cathode holes CH are present. Thus, at places where the plurality of cathode holes CH are present, the second planarization layer PLN and the first planarization layer PLN1 located under the bank BK may not be depressed or perforated as well (i.e., remained in a flat state).

The flat state of the respective portions of the upper surface of the bank BK located under the cathode holes CH may mean that one or more insulating layers or one or more metal patterns (e.g., one or more electrode, one or more lines, and/or the like), or the emission layer EL located under the cathode electrode CE have not been damaged by the process of forming the cathode holes CH in the cathode electrode CE.

A brief description for the process of forming cathode holes CH in the cathode electrode CE is as follows. A specific mask pattern may be deposited at respective locations where the cathode holes CH are to be formed, and then, a cathode electrode material may be deposited thereon. Accordingly, the cathode electrode material may be deposited only in an area where the specific mask pattern is not located, and thereby, the cathode electrode CE including the cathode holes CH may be formed.

The specific mask pattern may include, for example, an organic material. The cathode electrode material may include a magnesium-silver (Mg—Ag) alloy.

In one or more aspects, after the cathode electrode CE having the cathode holes CH is formed, the display panel 110 may be in a situation in which the specific mask pattern is completely removed, partially removed (where a portion of the specific mask pattern remains), or not removed (where all of the specific mask pattern remains without being removed).

As discussed above, while transistors (e.g., DT and/or ST) and a storage capacitor Cst may not be disposed in the optical area OA configured in the first type (the anode extension type) as in the examples of FIGS. 4 to 9, transistors (e.g., DT and/or ST) and one or more storage capacitors Cst may be disposed in the optical area OA configured in the second type (the hole type) as in the examples of FIGS. 10 to 12.

In the first type (anode extension type) of FIGS. 4 to 9, two or more light emitting elements ED may be disposed in the optical area OA, and two or more light emitting elements ED may be also disposed in the optical bezel area OBA, which is an area located outside of the optical area OA. Further, in the first type (anode extension type), transistors (e.g., DT and/or ST) and a storage capacitor Cst may not be disposed in the optical area OA, and transistors (e.g., DT and/or ST) and one or more storage capacitors Cst may be disposed in the optical bezel area OBA located outside of the optical area OA.

Referring to FIGS. 10 to 12, in the second type (hole type), two or more light emitting elements ED may be disposed in the optical area OA. That is, in the optical area OA of the second type (hole type), two or more light emitting elements ED may be disposed in the low-transmittable area LTA of the optical area OA. Further, in the second type (hole type), transistors (e.g., DT and/or ST) and one or more storage capacitors Cst may be disposed in the optical area OA. That is, in the optical area OA of the second type (hole type), transistors (e.g., DT and/or ST) and one or more storage capacitors Cst may be disposed in the low-transmittable area LTA of the optical area OA.

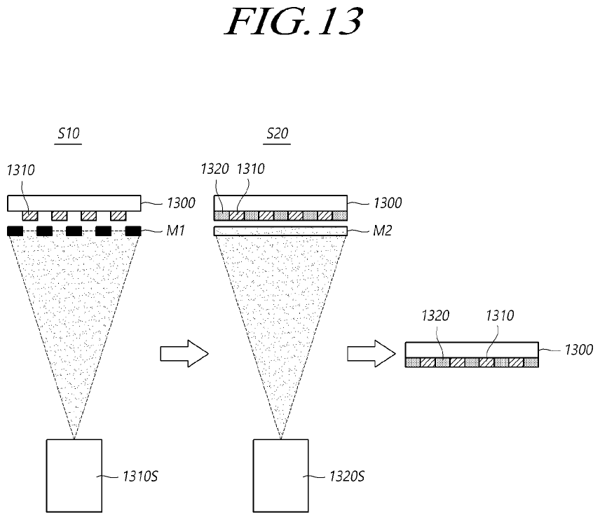

FIG. 13 illustrates an example cathode patterning process performed when manufacturing the display panel 110 according to aspects of the present disclosure.

Referring to FIG. 13, in one or more aspects, when manufacturing the display panel 110 according to aspects of the present disclosure, a cathode patterning process for forming a cathode electrode CE including a plurality of cathode electrodes CE may include a first deposition process S10 and a second deposition process S20.

The first deposition process S10 may be a step of forming a plurality of metal patterning layers MPL 1310. The metal patterning layers MPL 1310 may also be referred to simply as “patterning layers” or “cathode patterning layers”. The metal patterning layers MPL 1310 may be transparent or substantially transparent and/or may be more transparent than the cathode electrode CE.

In the first deposition process S10, a cathode patterning material CPM may be deposited on a substrate 1300 (which may be referred to as a preparation substrate) masked with a first mask M1 by a first evaporator 1310S, and thereby, a plurality of metal patterning layers MPL 1310 may be formed.

In this stage, the substrate 1300 used in the first deposition process S10 may be a substrate in a status before a cathode electrode CE is formed.

For example, the cathode patterning material CPM used in the first deposition process S10 may include a non-metal material. For example, the cathode patterning material CPM may include an organic material. The organic material included in the cathode patterning material CPM may, characteristically, include a material that inhibits nucleation. For example, the material for inhibiting nucleation may include a fluorine-substituted compound or the like.

For example, the first mask M1 used in the first deposition process S10 may be a fine metal mask FMM.

The second deposition process S20 may be a step of forming a cathode electrode CE 1320 having a plurality of cathode holes CH.

In the second deposition process S20, after placing a second mask M2 on the preparation substrate 1300 on which the plurality of metal patterning layers MPL 1310 are formed, a cathode metal may be deposited toward the preparation substrate 1300 by a second evaporator 1320S. In this stage, the cathode metal may be deposited in an area where the plurality of metal patterning layers MPL 1310 are not formed by avoiding the plurality of metal patterning layers MPL 1310. That is to say that the cathode metal is primarily deposited where the metal patterning layers MPL 1310 are not present due to a weak attraction between the cathode metal and material of the metal patterning layers MPL 1310. As such, the metal patterning layers MPL 1310 may interact weakly with metals and/or not adhere to metals.

In this manner, the cathode electrode CE 1320 having the plurality of cathode holes CH may be formed. In this implementation, the plurality of cathode holes CH may be areas in which the cathode metal has not been formed and the plurality of metal patterning layers MPL 1310 are formed.

The second mask M2 used in the second deposition process S20 may be, for example, an open metal mask OMM. For example, the cathode metal may be a magnesium-silver (Mg—Ag) alloy. In the second deposition process S20, the cathode metal may move to an area where the cathode patterning material CPM, which is a material of the plurality of metal patterning layers MPL 1310, is not placed, and thereby, a pattern (cathode electrode pattern) may be formed.

Hereinafter, a cathode patterning process technique used when manufacturing the display panel 110 according to aspects of the present disclosure may be referred to as a cathode patterning material (CPM) patterning process. The CPM patterning process technique according to aspects of the present disclosure may provide an advantage of preventing an area (or one or more elements) around a plurality of cathode holes CH from being damaged even when the plurality of cathode holes CH are formed.

In one or more aspects, according to the CPM patterning process technique, a plurality of metal patterning metal layers MPL 1310 may be respectively disposed in a plurality of cathode holes CH formed in a cathode electrode CE. That is, areas where the plurality of metal patterning metal layers MPL 1310 are disposed may correspond to the plurality of cathode holes CH.

Hereinafter, various aspects of the plurality of metal patterning metal layers MPL 1310 and an associated nearby structure will be described. It should be noted here that for convenience of description, discussions are provided based on examples where the second type (hole type) of optical area OA is implemented.

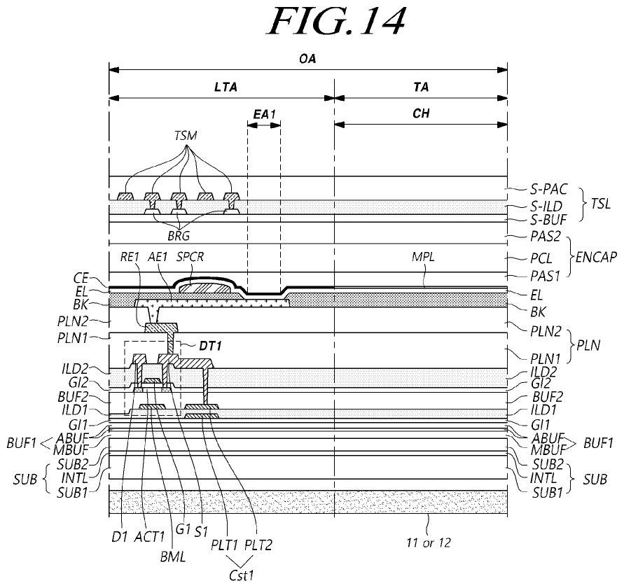

FIGS. 14 to 16 are example cross-sectional views of stackup configurations in an optical area OA of the display panel 110 according to aspects of the present disclosure.

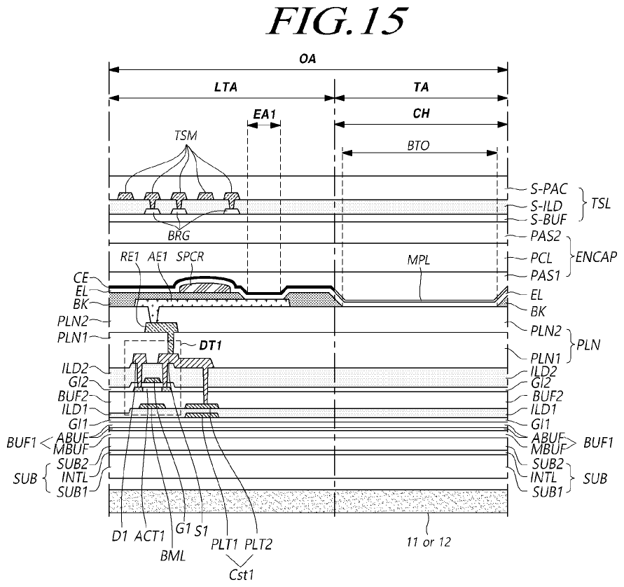

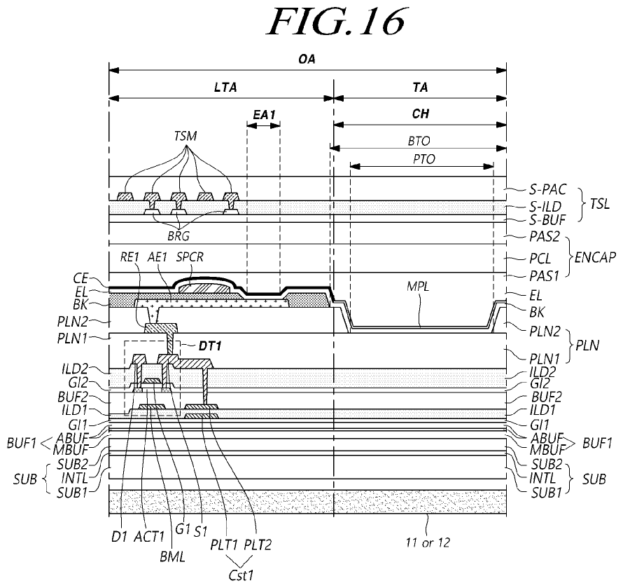

The cross-sectional view of FIG. 14 represents a part of the cross-sectional view of FIG. 12. A stack-up configuration in the cross-sectional view of FIG. 14 is substantially the same as the stack-up configuration in the cross-sectional view of FIG. 12 except that a metal patterning layer MPL is added. The cross-sectional views of FIGS. 15 and 16 represent a part of the cross-sectional view of FIG. 12. Stack-up configurations in the cross-sectional views of FIGS. 15 and 16 are substantially the same as the stack-up configuration in the cross-sectional view of FIG. 12 except that a metal patterning layer MPL is added and one or more elements (e.g., BK, PLN2, and/or the like) around the metal patterning layer MPL are modified. Taking account of such similarities, discussions on the examples of FIGS. 14 to 16 will be provided by focusing on features different from the features of the example of FIG. 12.

Referring to FIGS. 14 to 16, in one or more aspects, the display panel 110 according to aspects of the present disclosure may include: a substrate SUB including a display area DA that allows an image to be displayed, and includes an optical area OA allowing light to be transmitted and a normal area NA located outside of the optical area OA; a first driving transistor DT1 over the substrate SUB; a planarization layer PLN disposed over the first driving transistor DT1; a first anode electrode AE1 disposed in the optical area OA, located on the planarization layer PLN, and electrically connected to the transistor through a contact hole formed in the planarization layer PLN; a bank BK located on the first anode electrode AE1 and including a light emitting opening for exposing a portion of the first anode electrode AE1; and a first emission layer EL disposed in the optical area OA, and contacting a top surface of the portion of the first anode electrode AE1 exposed through the light emitting opening of the bank BK.

Referring to FIGS. 14 to 16, in one or more aspects, the display panel 110 according to aspects of the present disclosure may further include a cathode electrode CE commonly disposed in the optical area OA and the normal area NA, located on the first emission layer EL, and including a plurality of cathode holes CH in the optical area OA.

Referring to FIGS. 14 to 16, in one or more aspects, the display panel 110 according to aspects of the present disclosure may further include a plurality of metal patterning layers MPL respectively disposed in the plurality of cathode holes CH. The plurality of metal patterning layers MPL may include a non-metal material.

For example, the plurality of metal patterning layers MPL may include an organic material as a non-metal material. According to the CPM patterning process technique described with reference to FIG. 13, each of the plurality of metal patterning layers MPL may be in contact with an edge of, or an area adjacent to, the cathode electrode CE.

Referring to FIGS. 14 to 16, the metal patterning layer MPL may be disposed in a transmission area TA of the optical area OA. That is, the metal patterning layer MPL may be disposed in a light transmission path.

Referring to FIG. 14, the bank BK may be in an unetched state in the transmission area TA of the optical area OA. That is, in the transmission area TA of the optical area OA, the metal patterning layer MPL may be located on the bank BK, and the upper surface of the bank BK under the metal patterning layer MPL may be in a flat state that has not been damaged by etching (i.e. as originally deposited).

Referring to FIG. 15, the bank BK may have a respective opening BTO etched in each of a plurality of transmission areas TA in the optical area OA. Since the respective opening BTO of the bank BK in each of the plurality of transmission areas TA of the optical area OA is in a light transmission path, such an opening BTO may be hereinafter referred to as a bank transmission opening BTO.

Referring to FIG. 15, in other words, the bank BK may have a plurality of bank transmission openings BTO located in the light transmission path in the optical area OA.

Two types of openings, i.e., the light emitting opening and the bank transmission opening BTO may be formed in the bank BK. There is a difference between the light emitting opening and the bank transmission opening BTO in that a metal/cathode is present in the light emitting opening, but a metal is not present in the bank transmission opening BTO.

Referring to FIG. 15, the plurality of cathode holes CH in which the plurality of metal patterning layers MPL are disposed may respectively correspond to the plurality of bank transmission openings BTO. All or a portion of each of the plurality of cathode holes CH may overlap with all or a portion of each of the plurality of bank transmission openings BTO.

Referring to FIG. 15, the plurality of metal patterning layers MPL may correspond to the plurality of bank transmission openings BTO, respectively, and all or a portion of each of the plurality of metal patterning layers MPL may correspond to the plurality of bank transmission openings BTO, respectively.

As shown in FIG. 15, transmittance of the optical area OA may be increased as the bank transmission opening BTO is present in the transmission area TA of the optical area OA. In addition, since the bank transmission opening BTO is present in the transmission area TA of the optical area OA, outgassing caused by irradiation of ultraviolet light and resulting pixel shrinkage may be reduced or eliminated. As a result, the reliability of a corresponding light emitting element ED, such as an organic light emitting diode (OLED) may be improved by reducing or eliminating reduction of luminance and reduction of lifetime caused by the outgassing and the pixel shrinkage.

Referring to FIG. 16, the planarization layer PLN may have a respective opening PTO by being etched in each of a plurality of transmission areas TA in the optical area OA. Since the respective opening PTO of the planarization layer PLN in each of the plurality of transmission areas TA of the optical area OA is in a light transmission path, such an opening PTO may be hereinafter referred to as a planarization layer transmission opening PTO.

In other words, referring to FIG. 16, the planarization layer PLN may have a plurality of planarization layer transmission openings PTO in the optical area OA. The plurality of planarization layer transmission openings PTO may be located in the light transmission path and be arranged to correspond to the plurality of bank transmission openings BTO.

For example, metal may not be present in the bank transmission openings BTO. Likewise, metal may not be present in the planarization layer transmission openings PTO. This may mean that metal is not present in a vertical direction in an area (i.e., the transmission area TA) corresponding to the bank transmission opening BTO and the planarization layer transmission opening PTO.

Referring to FIG. 16, the planarization layer PLN may include a first planarization layer PLN1 and a second planarization layer PLN2 on the first planarization layer PLN1.

The first planarization layer PLN1 and the second planarization layer PLN2 may be the same material layer. For example, both the first planarization layer PLN1 and the second planarization layer PLN2 may include polyimide (PI). In one or more aspects, the first planarization layer PLN1 and the second planarization layer PLN2 may be different material layers. For example, the first planarization layer PLN1 may include polyimide (PI), and the second planarization layer PLN2 may be a material layer including photo acrylic (PAC). The photoacrylic may have excellent flattening properties and thus have excellent film formation uniformity on the surface thereof. As a result, a corresponding light emitting element may produce a uniform light emitting characteristic, and a resulting light transmission characteristic may be improved to become uniform.

The plurality of planarization layer transmission openings PTO may be formed in both the first planarization layer PLN1 and the second planarization layer PLN2, or may be formed only in the second planarization layer PLN2. Hereinafter, it is assumed that the plurality of planarization layer transmission openings PTO are formed only in the second planarization layer PLN2.

Referring to FIG. 16, in one transmission area TA in the optical area OA, a bank transmission opening BTO and a planarization layer transmission opening PTO may form one deep opening through which light may be transmitted better.

As shown in FIG. 16, transmittance of the optical area OA may be further increased as the bank transmission opening BTO and the planarization layer transmission opening PTO are present together in the transmission area TA of the optical area OA. In addition, since the bank transmission opening BTO and the planarization layer transmission opening PTO are present together in the transmission area TA of the optical area OA, outgassing caused by irradiation of ultraviolet light and resulting pixel shrinkage may be reduced or eliminated. As a result, the reliability of a corresponding light emitting element ED, such as an organic light emitting diode (OLED) may be improved by reducing or eliminating reduction of luminance and reduction of lifetime caused by the outgassing and the pixel shrinkage.

As described above, in the display device 100 according to aspects of the present disclosure, even when one or more optical electronic devices (11 and/or 12) are located under, or in a lower portion of, the display panel 110, it is desirable that the one or more optical electronic devices (11 and/or 12) may normally receive light (e. g., visible light, infrared light, or ultraviolet light). Therefore, it is desirable that the optical area OA overlapping with the one or more optical electronic devices (11 and/or 12) in the display panel 110 has a light transmission structure. Further, since the optical area OA overlapping with the one or more optical electronic devices (11 and/or 12) in the display panel 110 is included in the display area DA, it is desirable that the optical area OA includes light emitting areas EA.

In one or more aspects, the display area DA of the display device 100 according to aspects of the present disclosure may include a transmission area TA allowing light to be transmitted and a normal area NA, which is an area located outside of the transmission area TA.

The optical area OA may include a plurality of transmission areas TA and a low-transmittable area LTA different from the plurality of transmission areas TA. The low-transmittable area LTA may be an area through which light cannot be transmitted or an area through which light may be transmitted but having lower transmittance than the plurality of transmission areas TA.

In one or more aspects, in the display device 100 according to aspects of the present disclosure, a first light emitting element ED1 may include a first anode electrode AE1, a first emission layer EL, and a cathode electrode CE. The first light emitting element ED1 may form a first light emitting area EA1 in the optical area OA.

Accordingly, as shown in FIGS. 14 to 16, the first anode electrode AE1 included in the first light emitting element ED1 may be disposed in the low-transmittable area LTA of the optical area OA.

Meanwhile, as shown in FIGS. 14 to 16, in examples where the optical area OA is implemented in the second type (hole type), a first driving transistor DT1 configured to drive the first light emitting element ED1 may be disposed in the low-transmittable area LTA of the optical area OA. That is, the first driving transistor DT1 included in a first pixel circuit SPC and used to drive the first light emitting element ED1 may be disposed in the low-transmittable area LTA of the optical area OA.

Meanwhile, in examples where the optical area OA is implemented in the first type (anode extension type), the display area DA may further include an optical bezel area OBA surrounding the optical area OA, and the first driving transistor DT1 configured to drive the first light emitting element ED1 may not be disposed in the low-transmittable area LTA of the optical area OA, but be disposed in the optical bezel area OBA, which is an area outside of the optical area OA. That is, the first driving transistor DT1 included in the first pixel circuit SPC and used to drive the first light emitting element ED1 may be disposed in the optical bezel area OBA being an area outside of the optical area OA without being disposed in the low-transmittable area LTA of the optical area OA.

In the examples where the optical area OA is implemented in the first type (anode extension type), the display panel 110 may include a first anode extension line AEL interconnecting the first light emitting element ED1 disposed in the optical area OA and the pixel circuit SPC disposed in the optical bezel area OBA. For example, the first anode extension line AEL may include a transparent material.

As shown in FIGS. 14 to 16, in one or more aspects, the display device 100 according to aspects of the present disclosure may further include one or more optical electronic devices (11 and/or 12) (e.g., the one or more optical electronic devices (11 and/or 12) in the figures discussed above) located under a substrate SUB and overlapping with the optical area OA.

In one or more aspects, the optical area OA may include a first optical area OA1 (e.g., the first optical area OA1 in the figures discussed above) and a second optical area OA2 (e.g., the second optical area OA2 in the figures discussed above). In these aspects, the display device 100 according to aspects of the present disclosure may include a first optical electronic device 11 located under the substrate SUB and overlapping with the first optical area OA1, and a second optical electronic device 12 located under the substrate SUB and overlapping with the second optical area OA2.

The first optical electronic device 11 may perform a predefined operation by using first light transmitting through the first optical area OA1 and having a first wavelength. The second optical electronic device 12 may perform a predefined operation by using second light transmitting through the second optical area OA2 and having a second wavelength.

For example, in examples where the first optical electronic device 11 is a camera, and the second optical electronic device 12 is an infrared sensor, the first wavelength may be visible light wavelengths and the second wavelength may be infrared light wavelengths.

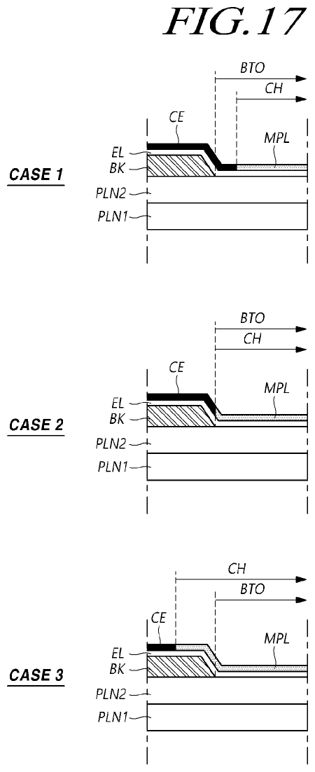

FIG. 17 illustrates example location relationships of a bank transmission opening BTO and a metal patterning layer MPL (which may correspond to a cathode hole CH) in the optical area OA of the display panel 110 according to aspects of the present disclosure.

Referring to FIG. 17, a cathode hole CH in which a metal patterning layer MPL is disposed may correspond to a bank transmission opening BTO. All or a portion of the cathode hole CH may overlap with all or a portion of the bank transmission opening BTO.

Referring to FIG. 17, the metal patterning layer MPL may correspond to the bank transmission opening BTO, and all or a portion of the metal patterning layer MPL may be disposed in the bank transmission opening BTO.

Referring to FIG. 17, example location relationships between the bank transmission opening BTO and the metal patterning layer MPL may include three cases (CASE 1, CASE 2, and CASE 3)

Referring to FIG. 17, in the first case 1, the cathode electrode CE may extend along at least one side surface of the bank BK to the inside of the bank transmission opening BTO.

In this case, an edge of the bank transmission opening BTO and an edge of the metal patterning layer MPL may be different from each other. That is, the edge of the bank transmission opening BTO and an edge of the cathode hole CH may be different from each other e.g. may not be aligned.

Further, the edge of the metal patterning layer MPL may be present in the bank transmission opening BTO without overlapping with the bank BK. The edge of the cathode hole CH may be present in the bank transmission opening BTO without being located on the bank BK. Since the metal patterning layer MPL is flat in this case, adhesion between the metal patterning layer MPL and underlying layer may be improved.

Referring to FIG. 17, in the second case CASE 2, the cathode electrode CE may extend along at least one side surface of the bank BK to the boundary of the bank transmission opening BTO.

In this case, an edge of the bank transmission opening BTO may be aligned with an edge of the metal patterning layer MPL. That is, the edge of the bank transmission opening BTO and an edge of the cathode hole CH may be aligned with each other.

Referring to FIG. 17, in the third case CASE 3, the metal patterning layer MPL may extend from the bank transmission opening BTO along at least one side surface of the bank BK, and overlap with the bank BK or be disposed over the bank BK. In CASE 3, the size of the cathode hole is increased relative to CASE 1 and CASE 2, increasing the transmissivity of the optical area OA. CASE 2 may be an option when a balance between CASE 1 and CASE 3 is desired.

In this case, an edge of the bank transmission opening BTO and an edge of the metal patterning layer MPL may not be aligned with each other (e.g., may be located in different locations in the horizontal direction). That is, the edge of the bank transmission opening BTO and an edge of the cathode hole CH may not be aligned with each other (e.g., may be located in different locations in the horizontal direction).

Further, the edge of the metal patterning layer MPL may be located over the bank BK. The edge of the cathode hole CH may be located over the bank BK.

Through the three cases in FIG. 17, an open ratio (or openness ratio) corresponding to the ratio of an area occupied by the metal patterning layer MPL to an area of the bank transmission opening (BTO) may be adjusted. Respective open ratios in the second case CASE 2 and the third case CASE 3 may be increased compared to the first case CASE 1.

For example, as the display panel 110 is designed to have a high open ratio, outgassing caused by irradiation of ultraviolet light and resulting pixel shrinkage may be more reduced or eliminated. As a result, the reliability of a corresponding light emitting element ED, such as an organic light emitting diode (OLED) may be improved by reducing or eliminating reduction of luminance and reduction of lifetime caused by the outgassing and the pixel shrinkage.

Hereinafter, example structures having various open ratios will be described.

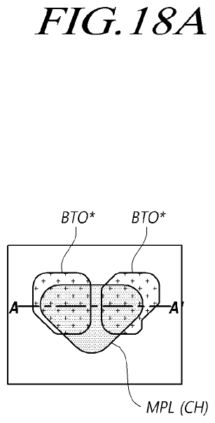

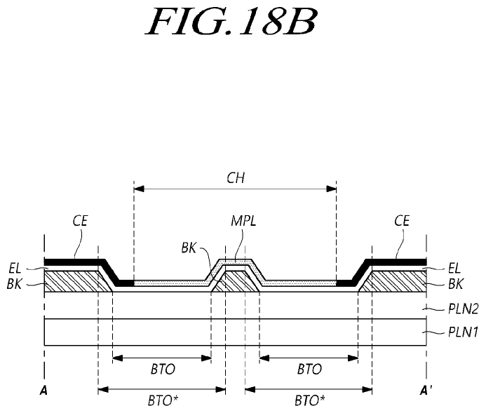

FIG. 18A illustrates an example planar structure when one metal patterning layer MPL overlap with two bank transmission openings BTO in the optical area OA of the display panel 110 according to aspects of the present disclosure. FIG. 18B is a cross-sectional view taken along line A-A′ of FIG. 18A.

Referring to FIGS. 18A and 18B, a bank BK may be disposed on a first planarization layer PLN1 and a second planarization layer PLN2. Two bank transmission openings BTO overlapping with one metal patterning layer MPL may be present in the bank BK.

Referring to FIGS. 18A and 18B, each of a plurality of metal patterning layers MPL may with two bank transmission openings BTO among a plurality of bank transmission openings BTO, and the two bank transmission openings BTO may be separated by a portion of bank BK.

Referring to FIGS. 18A and 18B, an area where one metal patterning layer MPL is disposed may be a cathode hole CH of the cathode electrode CE.

Referring to FIGS. 18A and 18B, one metal patterning layer MPL may include a first portion located over the second planarization layer PLN2, an intermediate portion located over a portion of a bank BK separating two bank transmission openings BTO, and a second portion located over the second planarization layer PLN2. For example, the intermediate portion may be located between the first portion and the second portion and may be disposed in a higher location from the substrate SUB (e.g. further from the substrate, for example, along the light transmission path) than the first portion and the second portion.

Referring to FIGS. 18A and 18B, since two bank transmission openings BTO overlapping with one metal patterning layer MPL are separated, an open ratio may be reduced.

Referring to FIG. 18A, each bank transmission opening BTO may be a respective open area between end points of the bank BK. The end points of the bank BK may be referred to as edges of the bank BK, and may be, for example, bottom points of side slopes of the bank BK.

Meanwhile, referring to FIG. 18A, each bank transmission opening BTO* labeled with an asterisk (*) may represent a respective area between starting points of side slopes of the bank BK.

As the side slopes of the bank BK become gentler, each bank transmission opening BTO* labeled with the asterisk (*) becomes increasingly larger than each bank transmission opening BTO. As the side slopes of the bank BK become steeper, each bank transmission opening BTO* labeled with the asterisk (*) becomes similar to each bank transmission opening BTO. When sides of the bank BK are vertical, each bank transmission opening BTO* labeled with the asterisk (*) may be equal to each bank transmission opening BTO.

Since the bank transmission opening BTO* labeled with the asterisk (*) is related to a time point at which a corresponding etching process is performed (a starting point at which each side slope of the bank BK runs), the bank transmission opening BTO* labeled with the asterisk (*) may be a term representing structural characteristics in terms of process.

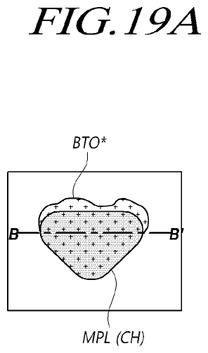

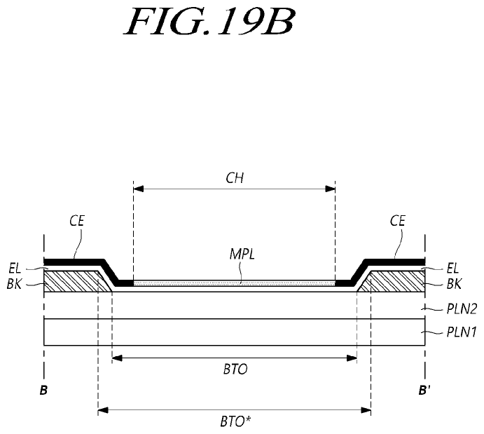

FIG. 19A illustrates an example planar structure when one metal patterning layer MPL overlap with one bank transmission opening BTO in an optical area OA of the display panel 110 according to aspects of the present disclosure. FIG. 19B is a cross-sectional view taken along line B-B′ of FIG. 19A.

Referring to FIGS. 19A and 19B, a bank BK may be disposed on a first planarization layer PLN1 and a second planarization layer PLN2. One bank transmission opening BTO overlapping with one metal patterning layer MPL may be present in the bank BK.

Referring to FIGS. 19A and 19B, each of a plurality of metal patterning layers MPL may overlap with one bank transmission opening BTO among a plurality of bank transmission openings BTO.

Referring to FIGS. 19A and 19B, since one bank transmission opening BTO overlap with one metal patterning layer MPL, an open ratio may increase. Therefore, in the process of evaluating reliability related to ultraviolet (UV) light in the manufacturing process, outgassing caused by irradiation of ultraviolet light and resulting pixel shrinkage may be reduced or prevented, and as a result, the reliability of a corresponding light emitting element ED, such as an organic light emitting diode (OLED) may be improved by reducing or eliminating reduction of luminance and reduction of lifetime caused by the outgassing and the pixel shrinkage.

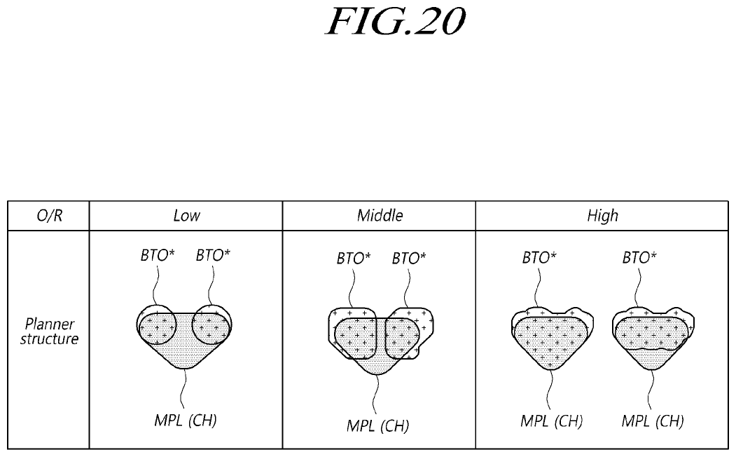

FIG. 20 illustrates example planar structures according to open ratios O/R of a bank BK in the optical area OA of the display panel 110 according to aspects of the present disclosure.

Referring to FIG. 20, when the number of bank transmission openings BTO* overlapping with one metal patterning layer MPL is two, the level of a corresponding open ratio O/R may be a low level Low and a middle level Middle.

Referring to FIG. 20, when the number of bank transmission openings BTO* overlapping with one metal patterning layer MPL is one, the level of a corresponding open ratio O/R may be a high level High.

Basically, n (n is a natural number greater than or equal to 1) number of bank transmission openings BTO among a plurality of bank transmission openings BTO may overlap with one metal patterning layer MPL among a plurality of metal patterning layers MPL.

For example, to ensure reliability even when irradiated with UV light, the open ratio of an area occupied by an overlapping with area of n bank transmission openings BTO with one metal patterning layer MPL to the total area of the n bank transmission openings BTO may exceed approximately 47%. For example, the level of an open ratio O/R of approximately 47% may be set to the middle level Middle.

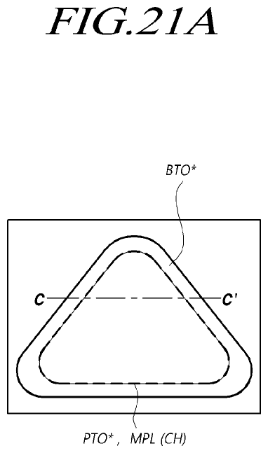

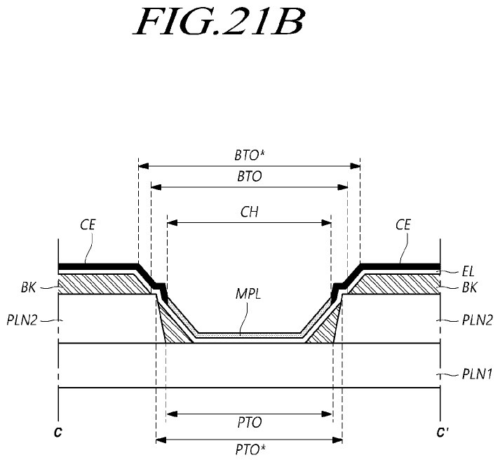

FIGS. 21A, 21B, 22A, 22B, 23A, and 23B illustrate example planar structures of three combinations of a metal patterning layer MPL, a bank transmission opening BTO, and a planarization layer transmission opening PTO in the optical area OA of the display panel 110 according to aspects of the present disclosure.

Hereinafter, each bank transmission opening BTO* labeled with the asterisk (*) may represent a respective area between starting points of side slopes of a bank BK.

As side slopes of the bank BK become gentler, each bank transmission opening BTO* labeled with the asterisk (*) becomes increasingly larger than each bank transmission opening BTO. As side slopes of the bank BK become steeper, each bank transmission opening BTO* labeled with the asterisk (*) becomes similar to each bank transmission opening BTO. When sides of the bank BK are vertical, each bank transmission opening BTO* labeled with the asterisk (*) may be equal to each bank transmission opening BTO.

Since the bank transmission opening BTO* labeled with the asterisk (*) is related to a time point at which a corresponding etching process is performed (a starting point at which each side slope of the bank BK runs), the bank transmission opening BTO* labeled with the asterisk (*) may be a term representing structural characteristics in terms of process.

Each planarization layer transmission opening PTO* labeled with the asterisk (*) may represent a respective area between starting points of side slopes of a second planarization layer PLN2.

As side slopes of the second planarization layer PLN2 become gentler, each planarization layer transmission opening PTO* labeled with the asterisk (*) becomes larger than each planarization layer transmission opening PTO. As side slopes of the second planarization layer PLN2 become steeper, each planarization layer transmission opening PTO* labeled with the asterisk (*) becomes similar to each planarization layer transmission opening PTO. When sides of the second planarization layer PLN2 are vertical, each planarization layer transmission opening PTO* labeled with the asterisk (*) may be equal to each planarization layer transmission opening PTO.

Since the planarization layer transmission opening PTO* labeled with the asterisk (*) is related to a time point at which a corresponding etching process is performed (a starting point at which each side slope of the second planarization layer PLN2 runs), the planarization layer transmission opening BTO* labeled with the asterisk (*) may be a term representing structural characteristics in terms of process.

FIG. 21A illustrates an example planar structure of a first combination of a metal patterning layer MPL, a bank transmission opening BTO, and a planarization layer transmission opening PTO in the optical area OA of the display panel 110 according to aspects of the present disclosure. FIG. 21B is a cross-sectional view taken along line C-C′ of FIG. 21A.

Referring to FIGS. 21A and 21B, a first bank transmission opening BTO among a plurality of bank transmission openings BTO, a first planarization layer transmission opening PTO among a plurality of planarization layer transmission openings PTO, and a first metal patterning layer MPL among a plurality of metal patterning layers MPL may correspond to each other.

Referring to FIGS. 21A and 21B, the first metal patterning layer MPL may overlap with side surfaces of the second planarization layer PLN2 of the planarization layer PLN adjacent to the first planarization layer transmission opening PTO. Both ends of the first metal patterning layer MPL may be disposed to extend along inclined side surfaces of a stack of a bank material. Referring to FIG. 21B, the stack of the bank material may include the same material as the bank BK, and be patterns located on sides of the second planarization layer PLN2.

Referring to FIGS. 21A and 21B, edges of the first metal patterning layer MPL may correspond to edges of the first bank transmission opening BTO or edges of the first planarization layer transmission opening PTO, or may be located between edges of the first bank transmission opening BTO and edges of the first planarization layer transmission opening PTO.

Referring to FIGS. 21A and 21B, in terms of the first bank transmission opening BTO* labeled with the asterisk (*) and the first planarization layer transmission opening PTO* labeled with the asterisk (*), the bank BK and the stack of the bank material (i.e., the patterns located on sides of the second planarization layer PLN2) may be separated from each other by edges of the first planarization layer transmission opening PTO* labeled with the asterisk (*). The first planarization layer transmission opening PTO* labeled with the asterisk (*) may overlap with the first metal patterning layer MPL. As respective locations of edges of the first metal patterning layer MPL are changed, edges of the first planarization layer transmission opening PTO* labeled with the asterisk (*) may overlap with edges of the first metal patterning layer MPL.

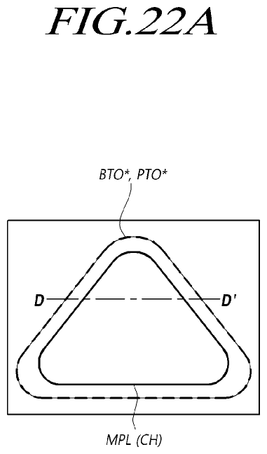

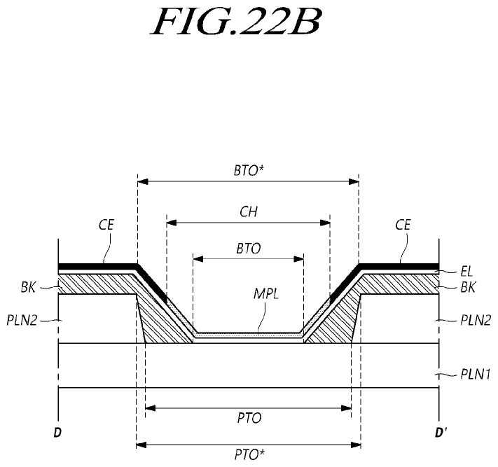

FIG. 22A illustrates an example planar structure of a second combination of the metal patterning layer MPL, the bank transmission opening BTO, and the planarization layer transmission opening PTO in the optical area OA of the display panel 110 according to aspects of the present disclosure. FIG. 22B is a cross-sectional view taken along line D-D′ of FIG. 22A.

Referring to FIGS. 22A and 22B, the first bank transmission opening BTO among the plurality of bank transmission openings BTO, the first planarization layer transmission opening PTO among the plurality of planarization layer transmission openings PTO, and the first metal patterning layer MPL among the plurality of metal patterning layers MPL may correspond to each other.

Referring to FIGS. 22A and 22B, side surfaces of the bank BK may overlap with side surfaces of the planarization layer PLN adjacent to the first planarization layer transmission opening PTO. Both ends of the first metal patterning layer MPL may be disposed to extend along inclined side surfaces of the bank BK.

Referring to FIGS. 22A and 22B, edges of the first metal patterning layer MPL may be located between edges of the first bank transmission opening BTO and edges of the first planarization layer transmission opening PTO.

Referring to FIGS. 22A and 22B, in terms of the first bank transmission opening BTO* labeled with the asterisk (*) and the first planarization layer transmission opening PTO* labeled with the asterisk (*), edges of the first bank transmission opening BTO* labeled with the asterisk (*) and edges of the first planarization layer transmission opening PTO* labeled with the asterisk (*) may be nearly, or substantially, aligned with each other.

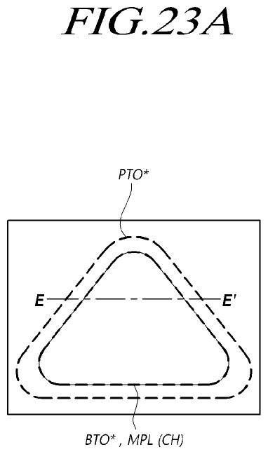

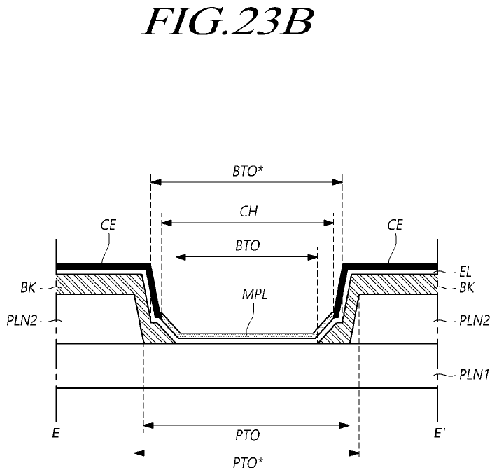

FIG. 23A illustrates an example planar structure of a third combination of the metal patterning layer MPL, the bank transmission opening BTO, and the planarization layer transmission opening PTO in the optical area OA of the display panel 110 according to aspects of the present disclosure. FIG. 23B is a cross-sectional view taken along line E-E′ of FIG. 23A.

Referring to FIGS. 23A and 23B, the first bank transmission opening BTO among the plurality of bank transmission openings BTO, the first planarization layer transmission opening PTO among the plurality of planarization layer transmission openings PTO, and the first metal patterning layer MPL among the plurality of metal patterning layers MPL may correspond to each other.

Referring to FIGS. 23A and 23B, the first metal patterning layer MPL may overlap with side surfaces of the bank BK adjacent to the first bank transmission opening BTO. Both ends of the first metal patterning layer MPL may be disposed to extend along respective inclined side surfaces disposed a lower location among respective two inclined side surfaces of the bank BK.

Referring to FIGS. 23A and 23B, edges of the first metal patterning layer MPL may be located between edges of the first bank transmission opening BTO and edges of the first planarization layer transmission opening PTO.

Referring to FIGS. 23A and 23B, the bank BK may have two inclined side surfaces. A respective boundary between the two inclined side surfaces may correspond to a respective edge of the first bank transmission opening BTO* labeled with the asterisk (*).

Referring to FIGS. 23A and 23B, in terms of the first bank transmission opening BTO* labeled with the asterisk (*) and the first planarization layer transmission opening PTO* labeled with the asterisk (*), edges of the first bank transmission opening BTO* labeled with the asterisk (*) may be nearly, or substantially, aligned with edges of the first metal patterning layer MPL.

Using the various structures described above, an open ratio corresponding to a ratio of an area occupied by the metal patterning layer MPL to an area of any one of the bank transmission opening BTO and the planarization layer transmission opening PTO may be adjusted by properly adjusting the size of each of the metal patterning layer MPL, the bank transmission opening BTO, and the planarization layer transmission opening PTO.

For example, as the display panel 110 is designed to have a high open ratio, outgassing caused by irradiation of ultraviolet light and resulting pixel shrinkage may be more reduced or eliminated. As a result, the reliability of a corresponding light emitting element ED, such as an organic light emitting diode (OLED) may be improved by reducing or eliminating reduction of luminance and reduction of lifetime caused by the outgassing and the pixel shrinkage.

The plurality of patterning layers MPL may have substantially the same thickness as the thickness of the cathode electrode CE.

A side surface of the plurality of patterning layers MPL and a side surface of the cathode electrode CE may be disposed in contact with or adjacent to each other.

The aspects of the touch display device 100 according to aspects of the present disclosure described above may be briefly discussed as follows.

According to aspects of the present disclosure, display device 100 may be provided that includes: a substrate including a display area that allows one or more images to be displayed, and includes an optical area allowing light to be transmitted and a normal area located outside of the optical area; a first driving transistor on the substrate; a planarization layer disposed on the first driving transistor; a first anode electrode disposed in the optical area, located on the planarization layer, and electrically connected to the first driving transistor through a contact hole of the planarization layer; a bank located on the first anode electrode, and including a light emitting opening for exposing a portion of the first anode electrode; a first emission layer disposed in the optical area and contacting an upper surface of the portion of the first anode electrode exposed through the light emitting opening; a cathode electrode commonly disposed in the optical area and the normal area, located on the first emission layer, and including a plurality of cathode holes in the optical area; and a plurality of metal patterning layers, each of which is disposed in a respective one of the plurality of cathode holes, and includes a non-metal material.

The bank may include a plurality of bank transmission openings located in a light transmission path in the optical area.

The plurality of cathode holes may respectively correspond to the plurality of bank transmission openings.

All or a portion of each of the plurality of cathode holes may overlap with all or a portion of each of the plurality of bank transmission openings.

The plurality of metal patterning layers may correspond to the plurality of bank transmission openings, respectively, and all or a portion of each of the plurality of metal patterning layers may correspond to the plurality of bank transmission openings, respectively.

The cathode electrode may be disposed to extend along at least one side surface of the bank to an inside portion of at least one of the plurality of bank transmission openings.

The cathode electrode may be disposed to extend along at least one side surface of the bank to a boundary of at least one of the plurality of bank transmission openings.

At least one of the plurality of metal patterning layers may be disposed to extend from at least one of the plurality of bank transmission openings along at least one side surface of the bank to an upper portion of the bank.

One metal patterning layer among the plurality of metal patterning layers may overlap with two bank transmission openings among the plurality of bank transmission openings, and the two bank transmission openings may be separated by a portion of the bank.

One metal patterning layer may include a first portion located over the planarization layer, an intermediate portion located over the portion of the bank separating the two bank transmission openings, and a second portion located over the planarization layer.

The intermediate portion may be located between the first portion and the second portion and may be disposed in a higher location from the substrate than the first portion and the second portion.

Each of the plurality of metal patterning layers may overlap with one bank transmission opening among the plurality of bank transmission openings.

The planarization layer may include a plurality of planarization layer transmission openings in the optical area.

The plurality of planarization layer transmission openings may be located in the light transmission path, and correspond to the plurality of bank transmission openings, respectively.

A first bank transmission opening among the plurality of bank transmission openings, a first planarization layer transmission opening among the plurality of planarization layer transmission openings, and a first metal patterning layer among the plurality of metal patterning layers may correspond to each other.

The first metal patterning layer may overlap with at least one side surface of the planarization layer adjacent to the first planarization layer transmission opening.

At least one side surface of the bank may overlap with at least one side surface of the planarization layer adjacent to the first planarization layer transmission opening.

The first metal patterning layer may overlap with at least one side surface of the bank adjacent to the first bank transmission opening.

At least one edge of the first metal patterning layer may be located between at least one edge of the first bank transmission opening and at least one edge of the first planarization layer transmission opening.

The plurality of metal patterning layers may include an organic material as a non-metal material, and each of the plurality of metal patterning layers may be in contact with an adjacent portion of the cathode electrode.

The optical area may include a plurality of transmission areas and a low-transmittable area different from the plurality of transmission areas.

The low-transmittable area may be an area through which light cannot be transmitted or an area through which light may be transmitted but having a lower transmittance than the plurality of transmission areas.

The first anode electrode may be disposed in the low-transmittable area.

A first light emitting element may be configured with the first anode electrode, the first emission layer, and the cathode electrode.

The first driving transistor may be configured to drive the first light emitting element.

The optical area may be implemented in any one of first and second types. When the optical area is implemented in the first type, the display area may further include an optical bezel area surrounding the optical area.

The first driving transistor may be disposed far away from the first light emitting element rather than being disposed closer to the first light emitting element. The first driving transistor may be disposed in the optical bezel area being an area outside of the optical area without being disposed in the low-transmittable area of the optical area. As a result, the transmittance of the optical area may be improved.

The display panel may further include an anode extension line electrically connecting the first light emitting element disposed in the optical area to a first pixel circuit disposed in the optical bezel area.

The anode extension line may be a transparent line including a transparent material. As a result, the transmittance of the optical area may be more improved.

When the optical area is implemented in the second type, the first driving transistor may be disposed closer to the first light emitting element in the optical area. The first driving transistor may be disposed in the low-transmittable area of the optical area.

The display device may further include one or more optical electronic devices located under the substrate and overlapping with the optical area.

The optical area may include a first optical area and a second optical area, which are different from each other.

In this implementation, the display device may further include a first optical electronic device located under the substrate and overlapping with the first optical area, and a second optical electronic device located under the substrate and overlapping with the second optical area.

The first optical electronic device may perform a first predefined operation using first light transmitting through the first optical area and having a first wavelength.

The second optical electronic device may perform a second predefined operation different from the first predefined operation by using second light transmitting through the second optical area and having a second wavelength different from the first wavelength.

According to aspects of the present disclosure, the display panel 110 may be provided that includes: a substrate including a display area that allows one or more images to be displayed, and includes an optical area allowing light to be transmitted and a normal area located outside of the optical area; a first driving transistor on the substrate; a planarization layer disposed on the first driving transistor; a first anode electrode disposed in the optical area, located on the planarization layer, and electrically connected to the first driving transistor through a contact hole of the planarization layer; a bank located on the first anode electrode, and including a light emitting opening for exposing a portion of the first anode electrode; a first emission layer disposed in the optical area and contacting an upper surface of the portion of the first anode electrode exposed through the light emitting opening; a cathode electrode commonly disposed in the optical area and the normal area, located on the first emission layer, and including a plurality of cathode holes in the optical area.

In the display panel, at least one of the bank and the planarization layer may include at least one transmission opening in a light transmission path in the optical area.

For example, only the bank among the bank and the planarization layer may have a transmission opening (a light transmission hole) in a transmission area (the light transmission path) in the optical area.

In another example, both the bank and the planarization layer may have transmission openings (light transmission holes) in a transmission area (the light transmission path) in the optical area.

In yet another example, only the planarization layer among the bank and the planarization layer may have a transmission opening (a light transmission hole) in a transmission area (the light transmission path) in the optical area.

According to the aspects described herein, the display panel 110 and the display device 100 may be provided that include a light transmission structure for enabling one or more optical electronic devices to normally receive light (e.g., visible light, infrared light, ultraviolet light, or the like) while not being exposed in a front surface of the display device.

According to the aspects described herein, the display panel 110 and the display device 100 may be provided that are capable of realizing a full screen display by using the entire area of the display panel as a display area by locating one or more optical electronic devices under the display area of the display panel such that the one or more optical electronic devices overlap with the display area of the display panel.

According to the aspects described herein, the display panel 110 and the display device 100 that are capable of enhancing reliability of light emitting elements by reducing decrease in luminance and decrease in lifetime in an optical area of the display panel overlapping with one or more optical electronic devices. Thus, by reducing decrease in luminance and decrease in lifespan of light emitting elements in the optical area, display panels and display devices having high efficiency and long lifespan (lifespan improvement) and enabling low power consumption design may be provided.

According to the aspects described herein, the display panel 110 and the display device 100 may be provided that include a bank structure suitable for an optical area of the display panel overlapping with one or more optical electronic devices.

According to the aspects described herein, the display panel 110 and the display device 100 may be provided that include a planarization layer structure suitable for an optical area of the display panel overlapping with one or more optical electronic devices.

According to the aspects described herein, the display panel 110 and the display device 100 may be provided that include a structure capable of improving transmittance of an optical area of the display panel overlapping with one or more optical electronic devices.

Additional features and aspects will be set forth in part in the description which follows and in part will become apparent from the description or may be learned by practice of the inventive concepts provided herein. Other features and aspects of the inventive concepts may be realized and attained by the structure particularly pointed out in, or derivable from, the written description, the claims hereof, and the appended drawings. Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the appended claims. Nothing in this section should be taken as a limitation on those claims.

The above description has been presented to enable any person skilled in the art to make, use and practice the technical features of the present disclosure, and has been provided in the context of a particular application and its requirements as examples. Various modifications, additions and substitutions to the described aspects will be readily apparent to those skilled in the art, and the principles described herein may be applied to other aspects and applications without departing from the scope of the present disclosure. The above description and the accompanying drawings provide examples of the technical features of the present disclosure for illustrative purposes only. That is, the disclosed aspects are intended to illustrate the scope of the technical features of the present disclosure.

It will be apparent to those skilled in the art that various modifications and variations can be made in the display device and the display panel of the present disclosure without departing from the spirit or scope of the aspects. Thus, it is intended that the present disclosure covers the modifications and variations of the aspects provided they come within the scope of the appended claims and their equivalents.

What is claimed is:

1. A display panel comprising:
a substrate comprising:
a display area in which one or more images are displayed;
an optical area configured to allow light to be transmitted through the substrate along a light transmission path; and
a normal area located outside the optical area;
a first driving transistor disposed on the substrate;
a planarization layer disposed on the first driving transistor;
a first anode electrode disposed in the optical area, located on the planarization layer, and electrically connected to the first driving transistor through a contact hole of the planarization layer;
a bank located on the first anode electrode and including a light emitting opening which exposes a portion of the first anode electrode;
a first emission layer disposed in the optical area and contacting a surface of the portion of the first anode electrode exposed through the light emitting opening;
a cathode electrode commonly disposed in the optical area and the normal area, located on the first emission layer and including a plurality of cathode holes in the optical area; and
a plurality of patterning layers respectively disposed in the plurality of cathode holes, and each patterning layer including a non-metal material.

2. The display panel of claim 1, wherein the bank comprises a plurality of bank transmission openings located in the light transmission path in the optical area,
wherein each one of the plurality of cathode holes corresponds to a respective one of the plurality of bank transmission openings; and
wherein all or a portion of each of the plurality of cathode holes overlaps with all or a portion of the respective bank transmission opening.

3. The display panel of claim 2, wherein the cathode electrode is disposed to extend along at least one side surface of the bank to an inside portion of at least one of the plurality of bank transmission openings.

4. The display panel of claim 2, wherein the cathode electrode is disposed to extend along at least one side surface of the bank to a boundary of at least one of the plurality of bank transmission openings.

5. The display panel of claim 2, wherein at least one of the plurality of patterning layers is disposed to overlap with the bank or to extend from at least one of the plurality of bank transmission openings along at least one side surface of the bank to an upper portion of the bank.

6. The display panel of claim 2, wherein one patterning layer among the plurality of patterning layers overlap with two bank transmission openings among the plurality of bank transmission openings, and the two bank transmission openings are separated by a portion of the bank.

7. The display panel of claim 6, wherein the one patterning layer comprises:
a first portion located over the planarization layer;
an intermediate portion located over the portion of the bank separating two bank transmission openings; and
a second portion located over the planarization layer,
wherein the intermediate portion is located between the first portion and the second portion, and the intermediate portion is disposed further from the substrate than the first portion and the second portion.

8. The display panel of claim 2, wherein each of the plurality of patterning layers overlap with one bank transmission opening among the plurality of bank transmission openings.

9. The display panel of claim 2, wherein the planarization layer comprises a plurality of planarization layer transmission openings in the optical area, and
wherein the plurality of planarization layer transmission openings are located in the light transmission path, and correspond to the plurality of bank transmission openings.

10. The display panel of claim 9, wherein a first bank transmission opening among the plurality of bank transmission openings, a first planarization layer transmission opening among the plurality of planarization layer transmission openings, and a first patterning layer among the plurality of patterning layers are disposed to correspond to each other, and
wherein the first metal patterning layer overlap with at least one side surface of the planarization layer adjacent to the first planarization layer transmission opening.

11. The display panel of claim 9, wherein a first bank transmission opening among the plurality of bank transmission openings, a first planarization layer transmission opening among the plurality of planarization layer transmission openings, and a first patterning layer among the plurality of patterning layers are disposed to correspond to each other, and
wherein at least one side surface of the bank overlap with at least one side surface of the planarization layer adjacent to the first planarization layer transmission opening.

12. The display panel of claim 9, wherein a first bank transmission opening among the plurality of bank transmission openings, a first planarization layer transmission opening among the plurality of planarization layer transmission openings, and a first patterning layer among the plurality of patterning layers are disposed to correspond to each other, and
wherein the first patterning layer overlap with at least one side surface of the bank adjacent to the first bank transmission opening.

13. The display panel of claim 9, wherein a first bank transmission opening among the plurality of bank transmission openings, a first planarization layer transmission opening among the plurality of planarization layer transmission openings, and a first patterning layer among the plurality of patterning layers are disposed to correspond to each other, and
wherein at least one edge of the first patterning layer is located between at least one edge of the first bank transmission opening and at least one edge of the first planarization layer transmission opening.

14. The display panel of claim 1, wherein the plurality of patterning layers comprises an organic material as a non-metal material, and each of the plurality of patterning layers is in contact with an adjacent portion of the cathode electrode.

15. The display panel of claim 1, wherein the optical area comprises a plurality of transmission areas and a low-transmittable area different from the plurality of transmission areas,
wherein the first anode electrode is disposed in the low-transmittable area, and
wherein the low-transmittable area is an area not allowing light to be transmitted or an area allowing light to be transmitted at a lower transmittance than the plurality of transmission areas.

16. The display panel of claim 15, wherein the optical area further comprises:
an optical bezel area surrounding the optical area,
a first light emitting element configured with the first anode electrode, the first emission layer, and the cathode electrode, and
wherein the first driving transistor is configured to drive the first light emitting element, and the first driving transistor is disposed in the optical bezel area being an area outside of the optical area without being disposed in the low-transmittable area of the optical area.

17. The display panel of claim 15, further comprising a first light emitting element configured with the first anode electrode, the first emission layer, and the cathode electrode, and
wherein the first driving transistor is configured to drive the first light emitting element, and the first driving transistor is disposed in the low-transmittable area of the optical area.

18. The display panel of claim 1, wherein the plurality of patterning layers have substantially a same thickness as the thickness of the cathode electrode.

19. The display panel of claim 1, wherein a side surface of the plurality of patterning layers and a side surface of the cathode electrode are disposed in contact with or adjacent to each other.

20. A display device comprising:
a substrate including a display area displaying one or more images, an optical area allowing light to be transmitted and a normal area located outside the optical area;
a first driving transistor on the substrate;
a planarization layer disposed on the first driving transistor;
a first anode electrode disposed in the optical area, located on the planarization layer, and electrically connected to the first driving transistor through a contact hole of the planarization layer;
a bank located on the first anode electrode, and comprising a light emitting opening for exposing a portion of the first anode electrode;
a first emission layer disposed in the optical area and contacting an upper surface of the portion of the first anode electrode exposed through the light emitting opening; and
a cathode electrode commonly disposed in the optical area and the normal area, located on the first emission layer, and comprising a plurality of cathode holes in the optical area,
wherein at least one of the bank and the planarization layer comprises at least one transmission opening in a light transmission path in the optical area.
